(19) United States
(12) Patent Application Publication
(10) Pub. No.: US 2012/0084031 A1
(43) Pub. Date: Apr. 5, 2012

(54) EQUIPMENT OPERATION STATE MEASUREMENT DEVICE, EQUIPMENT OPERATION STATE MEASUREMENT METHOD, AND CONTROL PROGRAM

(75) Inventors: Hiroshi SAITO, Shiga (JP); Maki ENDO, Kyoto (JP)

(73) Assignee: OMRON CORPORATION, Kyoto (JP)

(21) Appl. No.: 13/248,506

(22) Filed: Sep. 29, 2011

Related U.S. Application Data
(63) Continuation of application No. PCT/JP2010/056220, filed on Apr. 6, 2010.

(30) Foreign Application Priority Data
Apr. 10, 2009 (JP) 2009/096322
Mar. 8, 2010 (JP) 2010/050429

(51) Int. Cl. G06F 19/00; G01R 21/00

(52) U.S. Cl. 702/62

(57) ABSTRACT

The invention is directed towards an equipment operation state measurer having a power data acquirer and an operation state determiner. The power date acquirer acquires power consumption of equipment changing according to an operation state of the equipment. Additionally, a cause inputter accepts an input of a stop cause of the equipment from an operator, with respect to a stopped state determined by the operation state determiner, and sets the stop cause of the stopped state based on the input. Also, a computing unit obtains electric energy consumption for each stop cause, by integrating a period during which the stopped state corresponding to the stop cause continues and the power consumption in the period during which the stopped state continues, and is capable of measuring duration of the stopped state and the electric energy consumption for each stop cause of the equipment.

### CROSS-REFERENCE TO RELATED APPLICATIONS

This is a continuation application of PCT/JP2010/056220 filed Apr. 6, 2010, designating the United States of America, the disclosure of which, including the specification, drawings, and claims, is expressly incorporated by reference in its entirety. The disclosures of Japanese Patent Application No. 2009/096322, filed on Apr. 10, 2009 and Japanese Patent Application No. 2010/050429, filed on Mar. 8, 2010, including the specification, drawings, and claims is expressly incorporated by reference in their entireties

### TECHNICAL FIELD

The present invention relates to an equipment operation state measurer (or measurement device) that measures outage duration of equipment for each stop cause of the equipment that executes various processes in production lines, and an equipment operation state measurement method.

### BACKGROUND TECHNOLOGY

In order to improve productivity in production lines of factories and the like, it is essential to know an operating/stopped state of equipment that performs various processes. Thus, in general, the production lines are provided with an equipment operation state measurer that measures an operation state of each piece of equipment. Based on acquired measurement records on the operation state of each piece of equipment, a cause of a stop is determined for each piece of equipment so as to improve an operating rate and productivity of the equipment.

As such an equipment operation state measurer, an equipment operation state measurer described in Patent Literature 1, for example, is known. The equipment operation state measurer can determine an operation state (operating state/stopped state) of equipment based on a measurement result measured by a power meter installed in the equipment, and measure total time and total power consumption of the operating state/stopped state.

Patent Literatures 2 and 3 disclose equipment operation state measurers that receive operation state information for each piece of equipment from PLCs (programmable logic controllers) installed in each piece of equipment, and measure total duration of stopped states with respect to each stop cause.

Patent Literature 4 discloses an equipment operation state measurer that receives operation state information for each piece of equipment from PLCs installed in each piece of equipment, and records a stop/recovery time and a stop cause. This equipment operation state measurer allows an operator to input a stop cause when a PLC cannot automatically determine the stop cause.

### [Related Art]

### [Patent Literature]

Patent Literature 1: Japanese Patent Laid-open Publication No. 2001-52221 (Published on Feb. 23, 2001)

Patent Literature 2: Japanese Patent Laid-open Publication No. H5-200657 (Published on Aug. 10, 1993)
Patent Literature 3: Japanese Patent Laid-open Publication No. H6-282718 (Published on Oct. 7, 1994)
Patent Literature 4: Japanese Patent Laid-open Publication No. H7-323523 (Published on Dec. 12, 1995)

### SUMMARY OF THE INVENTION

### [Shortcomings Resolved by the Invention]

However, the conventional configurations described above have the following shortcomings.

Since the equipment operation state measurer described in Patent Literature 1 monitors power consumption of equipment in order to determine an operation state of the equipment, it cannot specify a stop cause of a stopped state. Therefore, it is unable to specify whether a cause that has stopped the equipment is due to a breakdown of the equipment, set-up (change of processing objects, jigs, or the like) due to a process change, or a replacement of consumable parts (cutting tools or the like). Thus, major stop causes of the equipment cannot be determined to improve an operating rate and productivity of the equipment. Therefore, it is impossible to take measures to reduce stopped states, which are considered wasteful.

On the other hand, the equipment operation state measurers described in Patent Literatures 2 to 4 acquire information regarding an operation state, including a cause of an equipment stop, from PLCs. Thus, they can acquire information regarding stop duration of equipment for each stop cause. Even when equipment is in a stopped state, however, it consumes some power. In other words, the equipment consumes power that associates with stopped states, such as stand-by power and the like. Since the PLCs cannot provide information on power consumption of equipment, the equipment operation state measurers in Patent Literatures 2 to 4 cannot acquire information regarding electric energy consumed by the equipment with respect to each stop cause. Therefore, it is difficult to investigate wasted electric energy consumption in the equipment in order to reduce power consumption of, for example, a factory, based on the information acquired from the equipment operation state measurers.

In addition, in order to acquire operation state information, including a cause of an equipment stop, from a PLC, an existing ladder program of the PLC needs to be modified. Alternatively, it is necessary to introduce a new PLC. A ladder program of a PLC controls equipment that is provided with the PLC. Thus, in a case where an existing PLC is used, a ladder program needs to be modified and tested for each PLC. In other words, a modification and test of the ladder program need to be performed on each piece of equipment. Thus, a circumstance arises where the cost to introduce a system including an equipment operation state measurer becomes high. This circumstance becomes more serious when equipment operation state measurers are introduced into a plurality of equipment.

In order to address the circumstances above, an object of the present invention is to provide an equipment operation state measurer that can be introduced with lower cost and that sets the detailed operation state (processing object information, stop cause, and the like) for each operation state that equipment experiences.

### [Object of the Invention]

In order to address the circumstances above, an equipment operation state measurer according to the present invention includes: a physical quantity acquirer that acquires a physical quantity changing according to an operation state of equipment; an operation state determiner that determines an operation state of the equipment based on the physical quantity; and an information inputter that accepts an input of information regarding (or relating to) a detailed operation state of the operation state determined by the operation state determiner, and sets the detailed operation state of the operation state based on the input.

In order to address the circumstances above, an equipment operation state measurement method according to the present invention includes: a physical quantity acquiring step that acquires a physical quantity changing according to an operation state of equipment; an operation state determining step that determines an operation state of the equipment based on the physical quantity; and an information inputting step that accepts an input of information regarding a detailed operation state of the operation state determined by the operation state determining step, and sets the detailed operation state of the operation state based on the input.

According to the above configuration, it is possible to determine an operation state of the equipment based on a physical quantity, accept an input of information regarding a detailed operation state of each of the determined operation states, and sets the detailed operation state of the operation state based on the input. Herein, the operation state may be, for example, an operating state, a stopped state, a power-off state, or the like. The detailed operation state is a detailed state that indicates characteristics of an operation state corresponding to the detailed operation state, for example, a stop cause or the like for a stopped state, and information on a processing object in a process or the like for an operating state.

With this configuration, it is possible to set information regarding a detailed operation state with respect to each operation state of the equipment. Based on this, a user can, for example, analyze a processing object, a stop cause and the like that are generating waste, in order to take measures to improve productivity of the equipment.

In application of the present invention, it is not necessary to modify a ladder program of a PLC that controls equipment. Therefore, it is possible to safely introduce the equipment operation state measurer of the present invention with reduced costs, as compared with a device that measures an operation state of equipment using a PLC.

The operation state determiner may determine whether an operation state of the equipment is an operating state or a stopped state based on the physical quantity. Further, the operation state determiner may determine whether or not an operation state is a power-off state.

The information inputter may accept an input of a stop cause as information regarding a detailed operation state of a stopped state determined by the operation state determiner, and may set the stop cause of the stopped state based on the input.

The information inputter may accept an input of information regarding a processing object as information regarding a detailed operation state of an operating state determined by the operation state determiner, and set the information regarding the processing object of the operating state based on the input.

The information inputter may accept an input of a power-off cause as information regarding a detailed operation state of a power-off state determined by the operation state determiner, and set the power-off cause of the power-off state based on the input.

According to the above configuration, it is also possible to set a detailed operation state of a power-off state. Thus, for example, it is possible to set a cause or the like that generates the power-off state as the detailed operation state. Based on this, a user can analyze the cause or the like that generates the power-off state in order to reduce waste of stand-by power or time in the power-off state.

The equipment operation state measurer may further include: a state information acquirer that acquires state information changing according to an operation state of the equipment; and a detailed operation state determiner that determines, based on the state information and an operation state determined by the operation state determiner, a detailed operation state of the operation state, and inputs information regarding the detailed operation state of the operation state into the information inputter.

According to the above configuration, the state information acquirer acquires state information of equipment. The detailed operation state determiner determines a detailed operation state of an operation state based on the state information and the operation state, and inputs information regarding the detailed operation state of the operation state into the information inputter.

Consequently, the equipment operation state measurer can automatically set a detailed operation state, thereby making it possible to omit an operation, for example, to input information regarding the detailed operation state by an operator.

The equipment operation state measurer may include a computer that obtains, with respect to each detailed operation state, a period during which an operation state corresponding to the detailed operation state continues; and obtains a representative value of the physical quantity from the period during which the operation state continues.

According to the above configuration, it is possible to obtain, with respect to each detailed operation state, a period during which an operation state corresponding to the detailed operation state continues, and a representative value of the physical quantity from the period during which the operation state continues.

With this configuration, it is possible to measure, with respect to each detailed operation state of equipment, duration of an operation state corresponding to the detailed operation state. Thus, based on this, a user can, for example, analyze a stop cause that generates waste of time, and thus can take measures to improve productivity of the equipment. In addition, based on this, a user can, for example, acquire information, such as which processing object being processed by equipment or which stop cause generates more stop states or the like. Therefore, the user can analyze a processing object or the like that is more likely to generate a stop state such as a breakdown or the like in an operating state, and thus can improve productivity of the equipment.

Herein, the physical quantity may be electric power, electric current, or the like. In such a case, a representative value of the physical quantity may be electric energy, average power, average current, total current value, or the like for the period. For example, when power consumption of equipment is measured, the equipment operation state measurer can obtain electric energy consumption of a stopped state with respect to each stop cause. Thus, it is possible to obtain an amount of power or current used during the stopped state. Thereby, a user can comprehend an amount of wastefully used power or current in order to take measures to reduce the amount of the wastefully used power or current.

When there is an operation state whose detailed operation state is not set, the information inputter may issue an alert to prompt for an input of information regarding the detailed operation state of the operation state.

The alert may be issued in the form of a display or a sound.

According to the above configuration, an operator can input information regarding a detailed operation state into the equipment operation state measurer before forgetting the detailed operation state of the operation state, thereby making it possible to keep accurate records on the operation states of the equipment.

The state information acquirer may acquire temperature information of the equipment as the state information.

According to the above configuration, the detailed operation state determiner can determine a detailed operation state of an operation state based on the temperature information, and input information regarding the detailed operation state of the operation state into the information input.

The state information acquirer may acquire vibration information of the equipment as the state information.

According to the above configuration, the detailed operation state determiner can determine a detailed operation state of an operation state based on the vibration information, and input information regarding the detailed operation state of the operation state into the information inputter.

The state information acquirer may acquire image information of a processing object of the equipment as the state information.

According to the above configuration, the detailed operation state determiner can determine a detailed operation state of an operation state based on the image information of the processing object, and input information regarding the detailed operation state of the operation state into the information inputter.

The equipment operation state measurer according to the present invention may include: a feature amount calculator that analyzes the physical quantity acquired by the physical quantity acquirer and calculates a feature amount of the physical quantity; and a detailed operation state estimator that refers to a first memory that stores a detailed operation state of an operation state and the feature amount of the physical quantity acquired by the physical quantity acquirer from a predetermined period before a start of the operation state, the detailed operation state of the operation state and the feature amount of the physical quantity being associated with each other. The detailed operation state estimator further uses a detailed operation state that is associated with the feature amount stored in the first memory and being most similar to the feature amount of the physical quantity acquired by the physical quantity acquirer from the predetermined period before the start of the operation state determined by the operation state determiner. The detailed operation state estimator further estimates the detailed operation state as a detailed operation state of the operation state determined by the operation state determiner. The detailed operation state estimator further inputs information regarding the estimated detailed operation state into the information inputter.

According to the above configuration, the detailed operation state estimator uses a detailed operation state, which is among detailed operation states of operation states stored in the first memory, that is associated with the feature amount stored in the first memory and being most similar to the feature amount of the physical quantity acquired by the physical quantity acquirer from the predetermined period before the start of the operation state determined by the operation state determiner. The detailed operation state estimator estimates the detailed operation state as a detailed operation state of the operation state determined by the operation state determiner. The detailed operation state estimator further inputs information regarding the estimated detailed operation state into the information inputter.

Thus, the equipment operation state measurer can automatically set a detailed operation state, thereby making it possible to omit an operation, for example, to input information regarding the detailed operation state by an operator.

The equipment operation state measurer according to the present invention may include a detailed operation state estimator that refers to a second memory that stores a detailed operation state of an operation state and a state transition sequence of a plurality of operation states including the operation state, the detailed operation state of the operation state and the state transition sequence being associated with each other. The detailed operation state estimator further extracts, from the second memory, a state transition sequence of an operation state that matches a state transition sequence of a plurality of operation states including the operation state determined by the operation state determiner. The detailed operation state estimator further estimates a detailed operation state that is associated with the extracted state transition sequence of the operation state as a detailed operation state of the operation state determined by the operation state determiner. The detailed operation state estimator further inputs information regarding the estimated detailed operation state into the information inputter.

According to the above configuration, the detailed operation state estimator estimates a detailed operation state of an operation state, which is among detailed operation states of operation states stored in the second memory, that matches a state transition sequence of the operation state as a detailed operation state of an operation state determined by the operation state determiner. The detailed operation state estimator further inputs information regarding the estimated detailed operation state into the information inputter.

Thus, the equipment operation state measurer can automatically set a detailed operation state, thereby making it possible to omit an operation, for example, to input information regarding the detailed operation state by an operator.

A portion of the equipment operation state measurer may be constructed by a computer. In such a case, the present invention includes a control program that provides the equipment operation state measurer by causing a computer to act as each of the above means. Furthermore, the present invention includes a computer-readable recording medium that stores the control program.

### [Effects of the Invention]

As described above, the present invention can set information regarding a detailed operation state for each operation state of equipment. Based on the information, a user can, for example, analyze a processing object, stop cause, or the like that generates waste, and thus can take measures to improve productivity of the equipment. In addition, when there is an operation state for which a detailed operation state is not set, the present invention issues an alert to prompt an input of the detailed operation state information. Thus, an operator can input information regarding a detailed operation state into the equipment operation state measurer before forgetting the detailed operation state of the operation state, thereby making it possible to keep accurate records on the operation states of the equipment.

Moreover, in application of the present invention, it is not necessary to modify a ladder program of a PLC that controls equipment. Therefore, it is possible to introduce the equipment operation state measurer of the present invention with reduced costs, as compared with a device that measures an operation state of equipment using a PLC.

Other objects, characteristics, and advantages of the present invention will be fully understood from the description hereinafter. Further, merits of the present invention will be evident from the following descriptions with reference to the accompanying drawings.

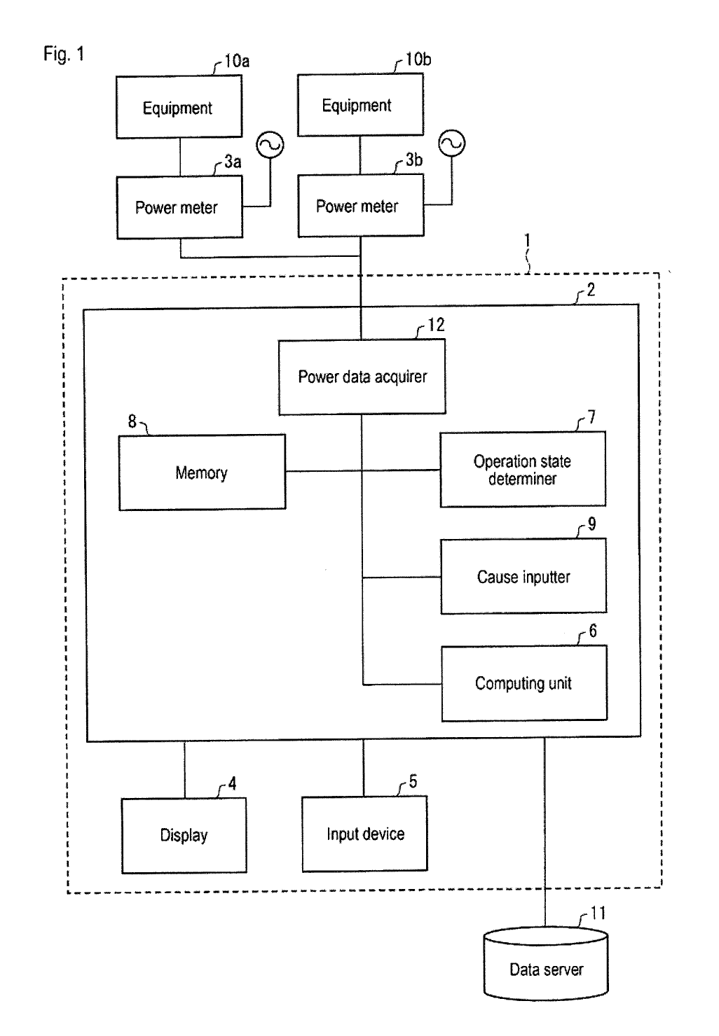

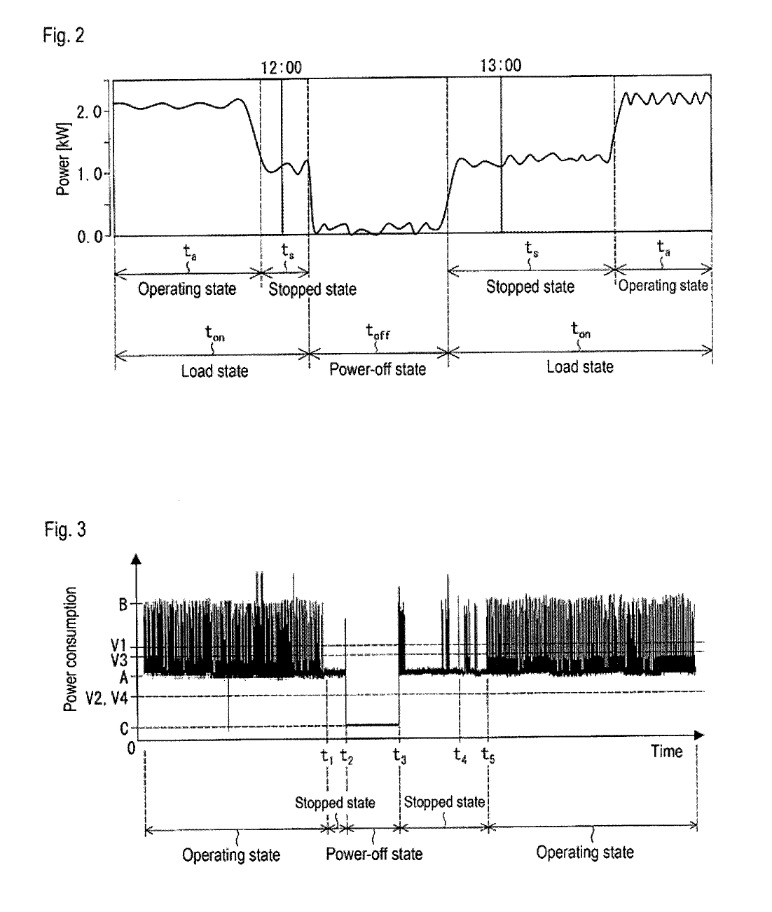

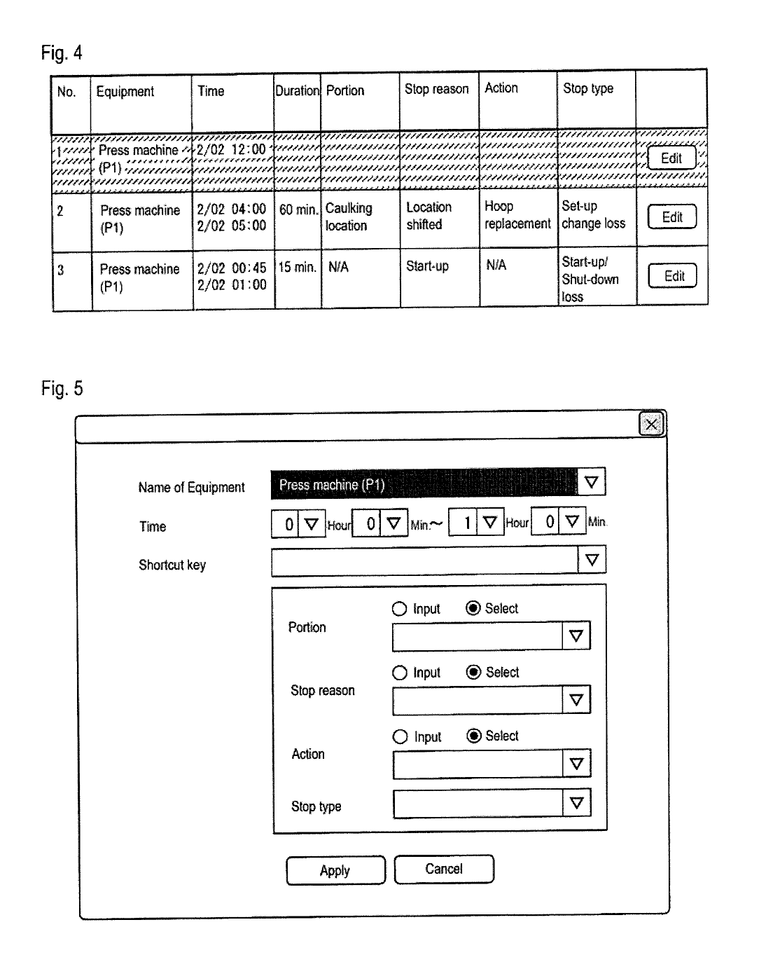

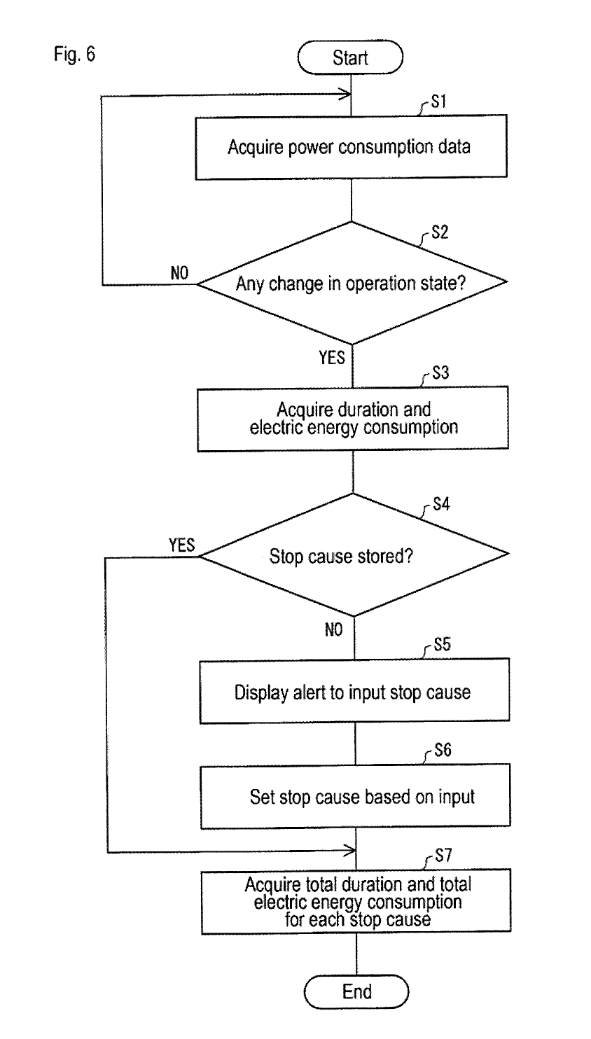

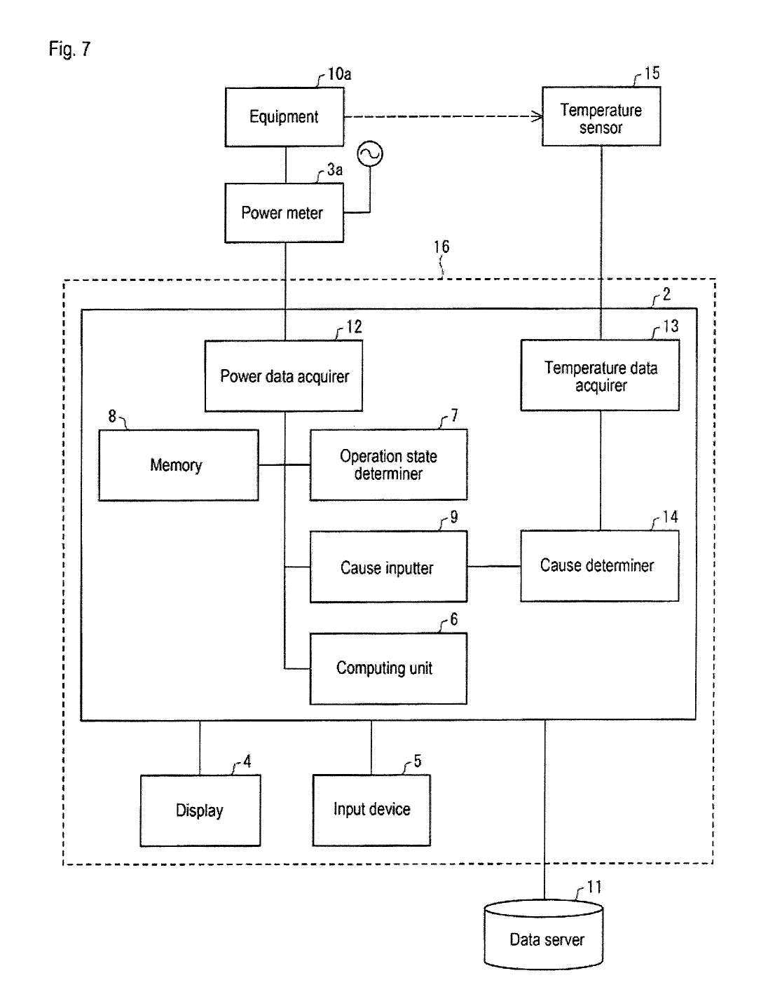

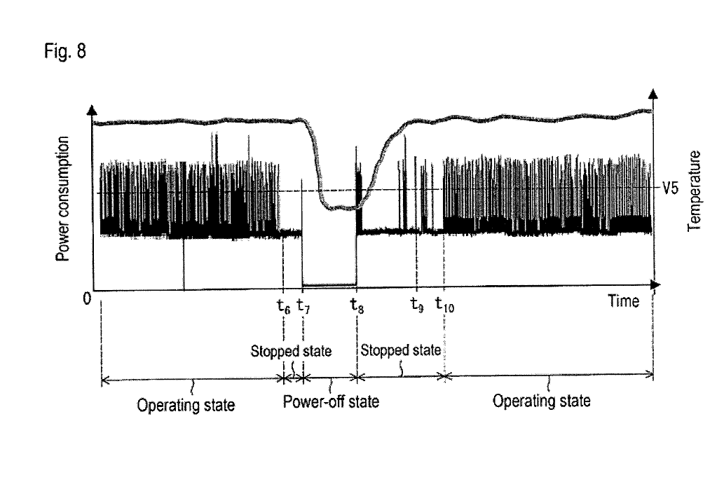

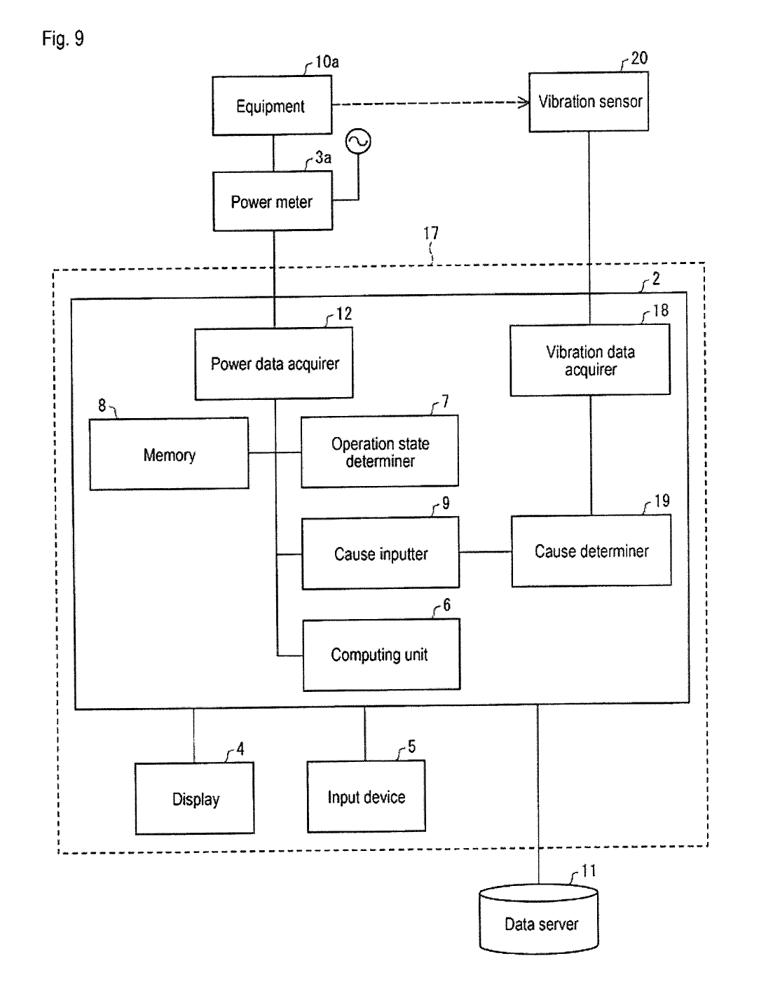

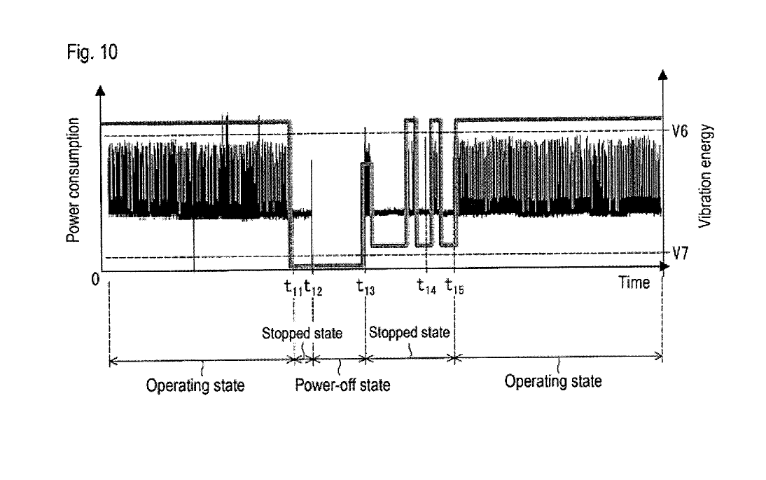

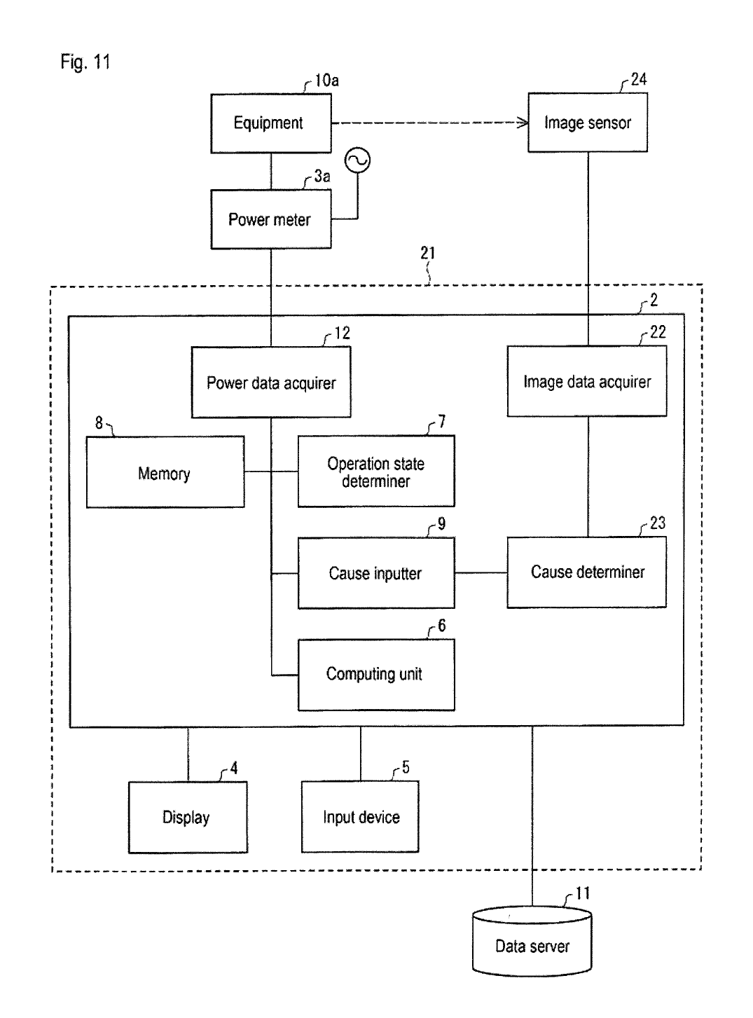

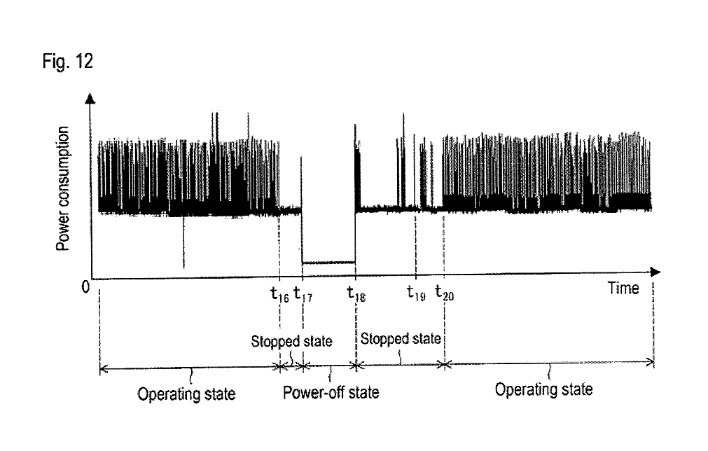

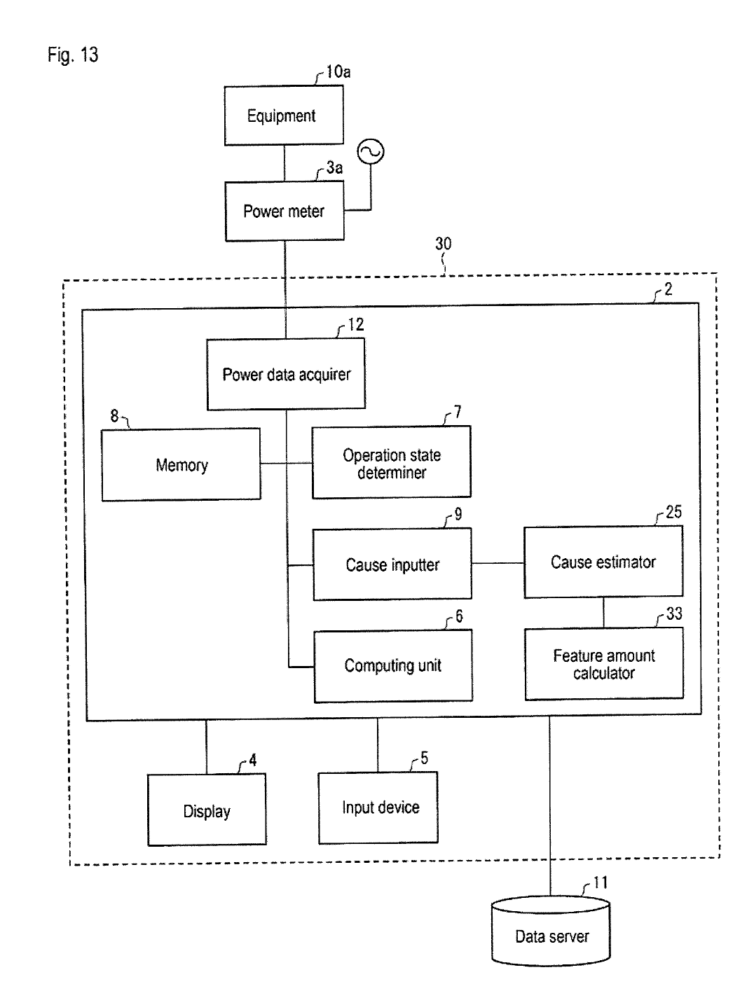

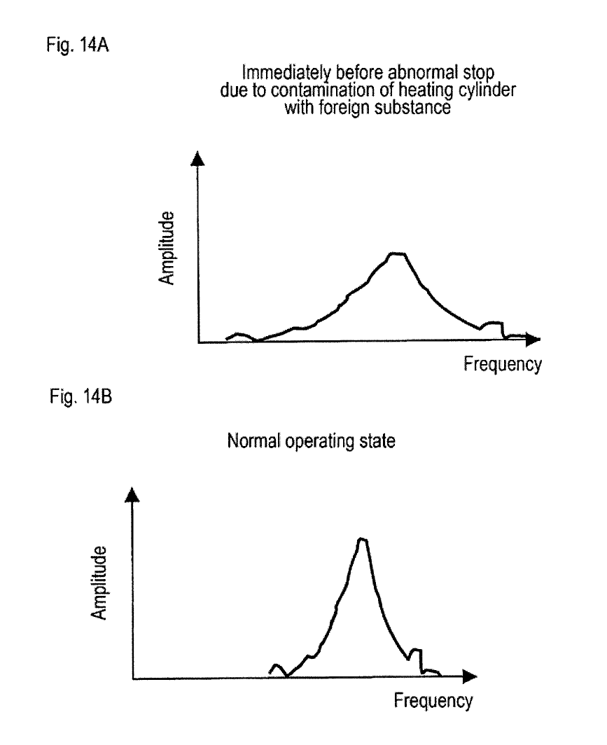

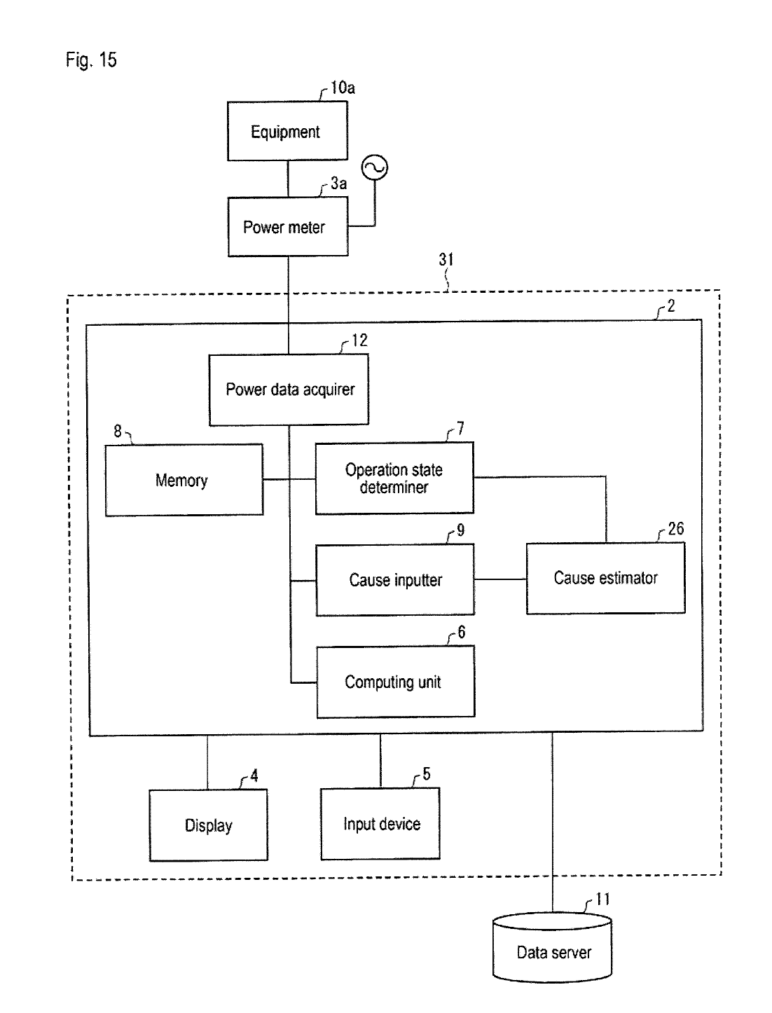

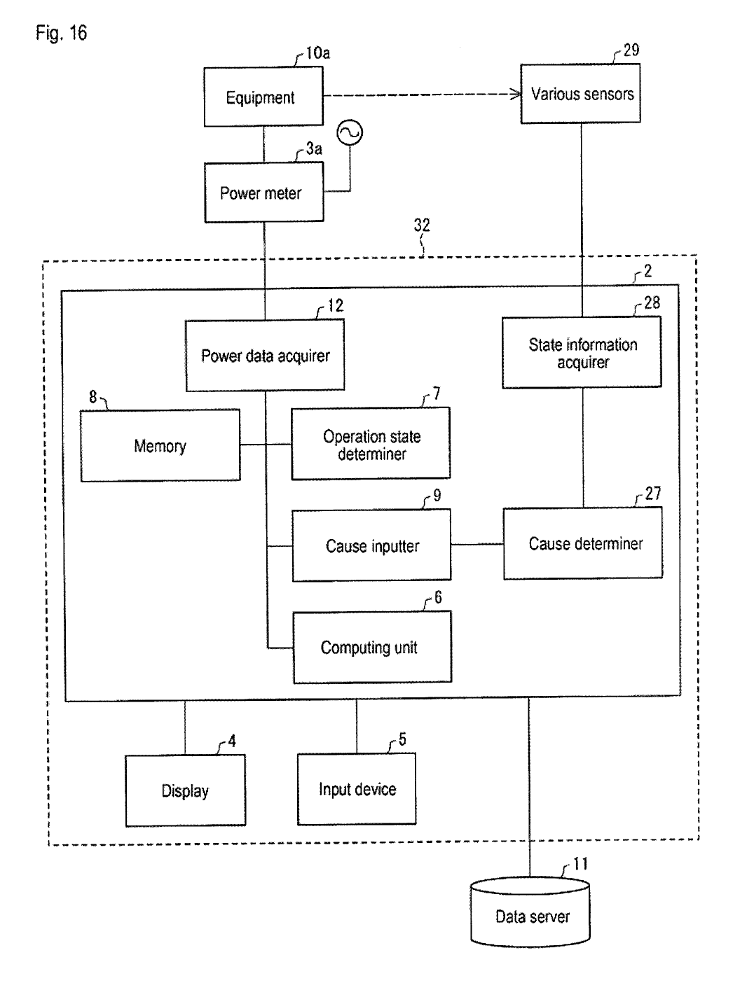

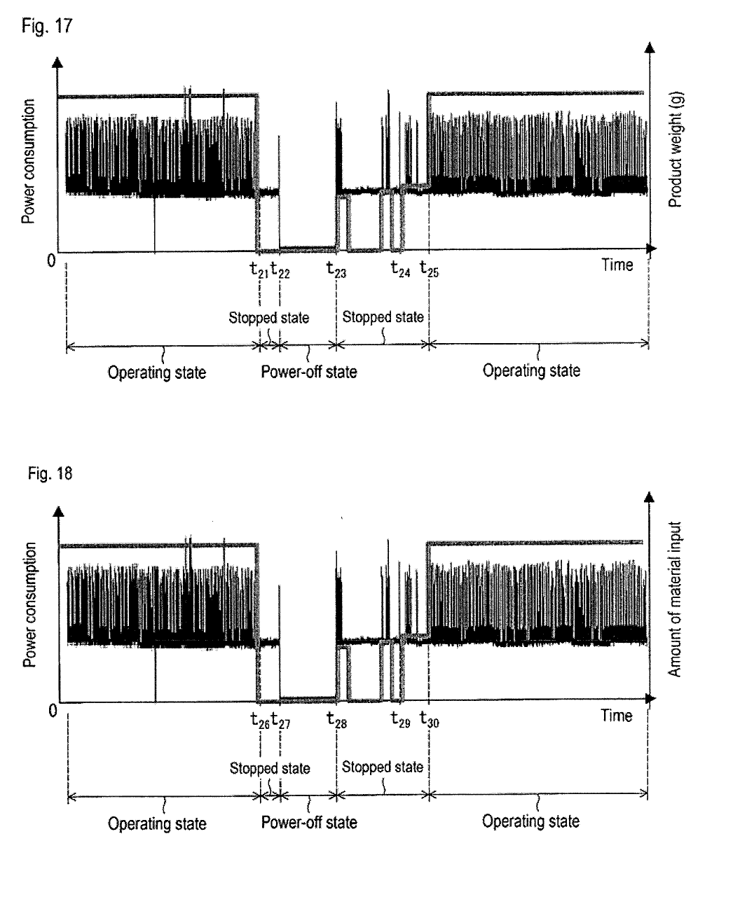

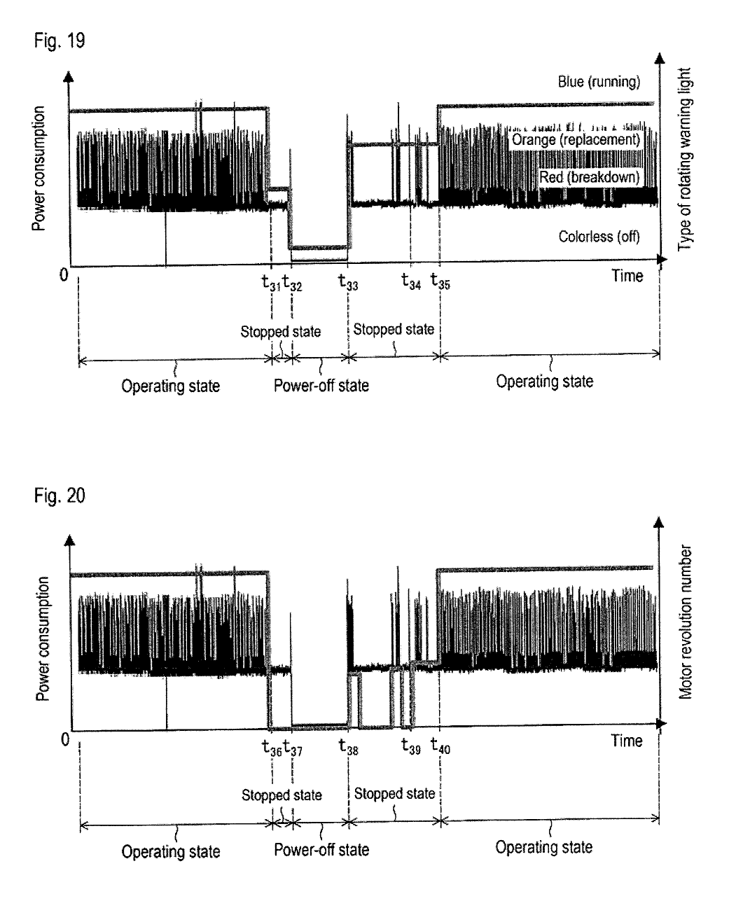

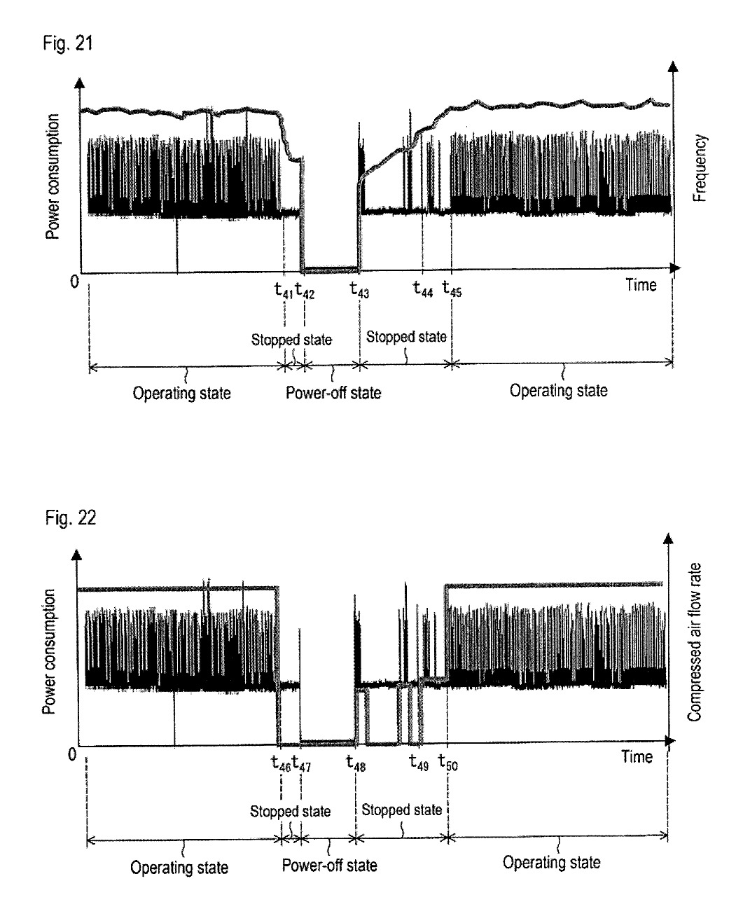

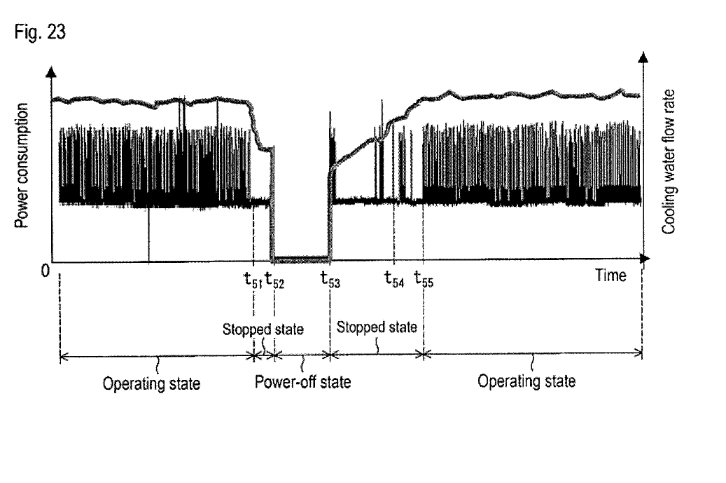

### BRIEF DESCRIPTION OF THE DRAWINGS

[FIG. 1] A block diagram illustrating a configuration of an equipment operation state measurer according to the present invention.

[FIG. 2] A chart illustrating an operational status of a press machine.

[FIG. 3] A chart illustrating an example of a graph that is a time series plot of power consumption of equipment measured by a power meter.

[FIG. 4] A diagram illustrating an example of an alert shown on a display for an operator.

[FIG. 5] A diagram illustrating an example of an input screen, on which an operator fills in each field regarding a stopped state.

[FIG. 6] A flowchart illustrating an example of a process flow performed in the equipment operation state measurer to record an operation state of equipment according to the present invention.

[FIG. 7] A block diagram illustrating a configuration of an equipment operation state measurer according to the present invention.

[FIG. 8] A chart illustrating an example of a graph that is a time series plot of power consumption of the equipment measured by the power meter and temperature of the equipment measured by a temperature sensor.

[FIG. 9] A block diagram illustrating a configuration of an equipment operation state measurer according to the present invention.

[FIG. 10] A chart illustrating an example of a graph that is a time series plot of power consumption of the equipment measured by the power meter and vibration energy obtained from vibration of the equipment and measured by a vibration sensor.

[FIG. 11] A block diagram illustrating a configuration of an equipment operation state measurer according to the present invention.

[FIG. 12] A chart illustrating an example of a graph that is a time series plot of power consumption of the equipment measured by the power meter.

[FIG. 13] A block diagram illustrating a configuration of an equipment operation state measurer according to the present invention.

[FIG. 14(a)] A chart illustrating frequency distribution as a result of a frequency analysis performed on power consumption data for a predetermined period immediately before an abnormal stop.

[FIG. 14(b)] A chart illustrating frequency distribution as a result of a frequency analysis performed on power consumption data for a normal operating state.

[FIG. 15] A block diagram illustrating a configuration of an equipment operation state measurer according to the present invention.

[FIG. 16] A block diagram illustrating a configuration of an equipment operation state measurer according to the present invention.

[FIG. 17] A chart illustrating an example of a graph that is a time series plot of power consumption of the equipment measured by the power meter and weight of products flowing on a line of the equipment measured by a weight sensor.

[FIG. 18] A chart illustrating an example of a graph that is a time series plot of power consumption of the equipment measured by the power meter and an amount of material input into the equipment measured by a material input sensor.

[FIG. 19] A chart illustrating an example of a graph that is a time series plot of power consumption of the equipment measured by the power meter and a color of a rotating warning light captured by an image sensor.

[FIG. 20] A chart illustrating an example of a graph that is a time series plot of power consumption of the equipment measured by the power meter and the number of motor revolutions measured by a motor revolution sensor.

[FIG. 21] A chart illustrating an example of a graph that is a time series plot of power consumption of the equipment measured by the power meter and a frequency of an inverter measured by a frequency sensor.

[FIG. 22] A chart illustrating an example of a graph that is a time series plot of power consumption of the equipment measured by the power meter and a flow rate of compressed air measured by a compressed air flow sensor.

[FIG. 23] A chart illustrating an example of a graph that is a time series plot of power consumption of the equipment measured by the power meter and a flow rate of cooling water measured by a cooling water flow sensor.

### EMBODIMENTS OF THE INVENTION

### First Embodiment

Hereinafter, an embodiment of the present invention is described in detail with reference to the drawings. Prior to the description of the present embodiment, states of object equipment are described with reference to FIG. 2.

FIG. 2 is a chart illustrating an operational status of a press machine. Specifically, FIG. 2 is a graph illustrating temporal fluctuation in power (kW) consumed by the press machine. FIG. 2 shows a graph of data for several hours. A press machine is used as an example of the object equipment in FIG. 2, however the same is applicable to other types of object equipment.

In the graph of FIG. 2, time t_{off}, in which power consumption is close to 0 kW, is a period when the press machine is powered off. This state is referred to as a power-off state. On the other hand, time tₒₙ, which is a period other than the time t_{off} in the power-off state, is a period when the press machine is powered on. This state is referred to as a load state.

Within a load-state time tₒₙ, time tₛ, in which power consumption is low, is a period when the press machine is stopped. This state is referred to as a stopped state. The press machine is consuming stand-by power even when it is stopped. Thus, there is room for reduction in electric energy consumed during the time tₛ. The stopped-state time tₛ can be determined by use of a conventional technology, for example, by employing a threshold value with respect to power consumption and the like. Thus, electric energy consumed during the time tₛ can be computed by the conventional technology.

On the other hand, within the load-state time tₒₙ, time tₐ, in which power consumption is high, is a period when the press machine is operating. This state is referred to as an operating state. The operating state includes a period when the press machine is actually performing a press operation, and also a period when the press machine is standing by due to, for example, carrying-in/out of processing objects. The power consumption of the press machine fluctuates in accordance with these periods.

FIG. 1 is a block diagram illustrating a configuration of an equipment operation state measurer 1 according to the present invention. The equipment operation state measurer 1 includes a calculator 2, a display (display) 4, and an input device 5. The calculator 2 includes a computing unit (computer) 6, an operation state determiner (operation state determiner) 7, a memory 8, a cause inputter (information inputter) 9, and a power data acquirer (physical quantity acquirer) 12. The input device 5 is configured with a keyboard, a mouse, a touch panel, or the like.

The equipment operation state measurer 1 measures operation states of equipment 10a and 10b that are arranged in production lines and execute various processes. The number of pieces of equipment, whose operation state is measured by the equipment operation state measurer 1, is not limited to two, and may be one, or three, or more. A power meter (equipment measurer) 3a is installed between the equipment 10a and a power source, and measures power consumption of the equipment 10a. Similarly, the power meter 3b measures power consumption of the equipment 10b.

Herein, an operation state is roughly divided into an operating state where a process, such as processing on a processing object, is executed in a normal way; a stopped state where a process is stopped or a process is not executed in a normal way; and a power-off state where the equipment is turned off. A stop cause that causes a stopped state includes a breakdown or an unexpected abnormality of the equipment 10a and 10b, set-up (change of processing objects, jigs, or the like) due to a change of processes, a replacement of consumable parts (cutting tools or the like), a start-up (warm-up after powering on or the like) and a shut-down (preparation before powering off or the like) of the equipment 10a and 10b, a scheduled stoppage (production adjustment, holiday, regular break, or the like) of the equipment 10a and 10b, or the like. For instance, a stoppage of processes due to a breakdown or an unexpected abnormality of the equipment 10a and 10b is waste of time, and is considered to be a stop cause whose occurrence should be reduced in order to improve productivity. Further, other stop causes excluding a stop cause due to a scheduled stoppage are also considered to be stop causes whose duration should be reduced in order to improve productivity. Furthermore, power consumed in a stopped state is also considered to be a waste. In addition, time and stand-by power for a power-off state generated by an unscheduled power-off cause (breakdown, or the like, for example) are also considered to be a waste.

The power consumption of the equipment 10a and 10b varies depending on their operation states. In general, more power is consumed in an operating state than in a stopped state. Even in the stopped state, however, functions of the equipment 10a and 10b are not completely shut down. For instance, a cooling fan may be running, power-operated doors or the like may be opened/closed according to an instruction of an operator, or a display panel to show information to an operator may be working. In addition, the equipment 10a and 10b consume a small amount of power as stand-by power even in a power-off state.

FIG. 3 is a chart illustrating an example of a graph that is a time series plot of power consumption of the equipment 10a measured by the power meter 3a. The vertical axis of the graph indicates power consumption, and the horizontal axis indicates time (clock time). In the example of FIG. 3, a time t₁ is 14:00, a time t₂ is 14:20, a time t₃ is 14:50, a time t₄ is 15:40, and a time t₅ is 16:00.

For example, during a period at or before the time t₁, in which power consumption is large, the equipment 10a is in an operating state. Even in the operating state, however, the power consumption is not constant and wildly changes between A and B according to the operation of the equipment 10a. In a case where the equipment is a press machine, for example, large power consumption reaching the value of B corresponds to a timing of pressing a processing object. Small power consumption around the value of A corresponds to a timing of carrying in and/or out of processing objects. In other words, in spite of the power consumption value being A, the period at or before the time t₁ is an operating state where the equipment 10a is operating in a normal way.

On the other hand, during a period between the time t₂ and the time t₃, the power consumption value is constantly C and is lower than A and close to 0. During the period between the time t₂ and the time t₃, the equipment 10a is in a power-off state where the power thereof is turned off. Further, a stand-by power value of the equipment 10a is C.

During a period between the time t_{i and the time t}₂, the power consumption is A and is substantially constant. During the period between the time t₁ and the time t₂, the equipment 10a is in a power-on state but not executing a regular process, such as processing on a processing object or the like. In this state, for example, processes are stopped due to an occurrence of an abnormality or the like in the equipment. Even in such a case, as described above, for example, a cooling fun may be running, or a display panel to show information to an operator may be working. Thus, the power consumption is larger than that for the period between the time t₂ and the time t₃. In other words, the period between the time t₁ and the time t₂ is a stopped state where no normal processing is executed. Therefore, the time and power consumed during the period between the time t₁ and the time t₂ is a waste that should be reduced.

Further, during the period between the time t₃ and the time t₅, the power consumption value is substantially A, but occasionally becomes large. The equipment 10a is turned on at the time t₃, and thereafter until the time t₅, the equipment 10a is performing, for example, a test run, set-up, or the like. Therefore, the power consumption of the equipment 10a is large due to a start-up, immediately after the time t₃ when the equipment 10a is powered on. Further, until the time t₅, the power consumption value occasionally reaches around B due to the test run or the like. That is, the period between the time t₃ and the time t₅ is also a stopped state where no normal processing is executed. Therefore, the time and power consumed during the period between the time t₃ and the time t₅ is a waste that should be reduced.

Similar to the period at or before the time t₁, during a period at or after the time t₅, the equipment 10a is in an operating state where it is executing predetermined processing in a normal way.

It is possible to determine whether the equipment 10a and 10b are in an operating state/stopped state by analyzing data of power consumption of the equipment 10a and 10b measured by the power meters 3a and 3b.

The power data acquirer 12 of the equipment operation state measurer 1 acquires data indicating power consumption of the equipment 10a and 10b from the power meters 3a and 3b, and stores the data in the memory 8. The operation state determiner 7 acquires the power consumption data from the memory 8 at every predetermined timing, and analyzes the data. The operation state determiner 7 acquires time information from an internal clock (time measurer) of the calculator 2, and stores the time information in the memory 8 while associating the time with the power consumption.

The operation state determiner 7 acquires the power consumption data of the equipment 10a from the memory 8, for example, every one minute, and obtains average power consumption for the one minute. The period for obtaining the average power consumption is set long enough with respect to a cycle of rise and fall in the power consumption of the equipment 10a in an operating state. In this example, one cycle of processing by the equipment 10a is about 20 seconds. Even when the equipment 10a is in an operating state where it is executing processing in a normal way, the power consumption of the equipment 10a wildly changes depending on moment to moment operation of the equipment 10a. Thus, average power consumption for a short period (one second, for example) greatly fluctuates in an operating state. Therefore, an operation state of the equipment 10a can be determined based on the average power consumption obtained for a period that is long enough with respect to the cycle of rise and fall in the power consumption of the equipment 10a. In the period at or before the time t₁ when the equipment 10a is in an operating state, average power consumption for one minute has a value between A and B. For example, a first threshold value V1 is set as a value between A and B and is compared with the average power consumption for the one minute (or electric energy consumption for the one minute). When the average power consumption for the one minute is larger than the first threshold value V1, the operation state determiner 7 determines that the equipment 10a is in an operating state.

In a case where a second threshold value V2 is set as a value between A and C, average power consumption for one minute in the period between the time t₁ and the time t₂ is smaller than or equal to the first threshold value V1 and also larger than the second threshold value V2. Thus, the equipment 10a is determined to be in a stopped state where it is not executing processing in a normal way. Since the second threshold value V2 is a value between A and C, in the period between the time t₁ and the time t₂, it is determined that the equipment 10a is in a stopped state but the power thereof is on.

Further, in the period between the time t₂ and the time t₃, average power consumption for one minute is smaller than the second threshold value V2 and also larger than 0. In this case, it is determined that the equipment 10a is in a power-off state where the power thereof is off.

During the period between the time t₃ and the time t₅, average power consumption for one minute is smaller than or equal to the first threshold value V1 and also larger than the second threshold value V2, and thus the equipment 10a is in a stopped state. However, the average power consumption for one minute wildly changes from moment to moment. The equipment 10a may be performing, for example, a test run or the like around the time t₄, and the average power consumption for a short period like one minute is not distinctively different from the average power consumption of an operating state. Therefore, there may be a case where an operating state cannot be distinguished from the stopped state around the time t₄.

Thus, the operation state determiner 7 acquires, from the memory 8, power consumption data of the equipment 10a for predetermined duration in the past (10 minutes in the past, for example) every one minute, for example. Further, a third threshold value V3 is set as a value between A and B. When average power consumption for latest one minute is larger than the first threshold value V1 but the average power consumption for the ten minutes in the past is smaller than or equal to the third threshold value V3, the equipment 10a may be determined to be in a stopped state where it is not executing processing in a normal way. In the example shown in FIG. 3, the third threshold value V3 is smaller than the first threshold value V1. However, the third threshold value V3 may be larger than or equal to the first threshold value V1.

Alternatively, the operation state determiner 7 may acquire, from the memory 8, power consumption data of the equipment 10a for predetermined duration in the past (11 minutes in the past, for example: between a time t_{a and a time (t}ₐ+11 minutes)) every one minute, for example. Then the operation state determiner 7 may obtain average power consumption for a period between a time (tₐ+5 minutes) and a time (tₐ+6 minutes). When the average power consumption for a period between the time (tₐ+5 minutes) and the time (tₐ+6 minutes) is smaller than or equal to the second threshold value V2, the operation state determiner 7 determines that the equipment 10a is in a stopped state during the period between the time (tₐ+5 minutes) and the time (tₐ+6 minutes). In a case where the average power consumption for the period between the time (tₐ+5 minutes) and the time (tₐ+6 minutes) is larger than the second threshold value V2, the operation state determiner 7 may determine that the equipment 10a is in an operating state during the period between the time (tₐ+5 minutes) and the time (tₐ+6 minutes), when average power consumption for five minutes from the time (tₐ) to the time (tₐ+5 minutes) or the average power consumption for five minutes from the time (tₐ+6 minutes) to the time (tₐ+11 minutes) is larger than a fourth threshold value V4 (same value as the second threshold value V2, for example) set as a value between A and C.

In other words, the operation state determiner 7 may determine an operation state of a target period based on average power consumption of the target period for determining the operation state, and average power consumption in antecedent and subsequent periods. Thereby, the operation state determiner 7 can determine that the equipment 10a is in a stopped state where the equipment 10a is not executing a predetermined process in the period between the time t₃ and the time t₅.

It is assumed here that the operation state determiner 7 determines, by use of the above determination method, that the equipment 10a is: in an operating state during the period at or before the time t₁ and the period at or after the time t₅; in a stopped state during the period between the time t₁ and the time t₂ and the period between the time t₃ and the time t₅; and in a power-off state during the period between the time t₂ and the time t₃. The operation state determiner 7 stores the determination result on the operation state in the memory 8 while associating the operation state with its time (period). The time and power consumed in a stopped state is a waste to be reduced. In order to take measures for the reduction, it is necessary to understand or record details of the causes that generate each stopped-state time. The operation state determiner 7 determines a state of the equipment 10a and 10b, such as an operating state, a stopped state, or a power-off state, based on the power consumption of the equipment 10a and 10b. However, the operation state determiner 7 cannot determine details of each state, such as stop causes and the like, based on the power consumption only.

When a period is determined to be a stopped state, the cause inputter 9 shows a time of occurrence and a determination result of the stopped state on the display 4 so that an operator can input a cause (stop cause) that has generated the stopped state into the calculator 2 via the input device 5. Further, when there is a stopped state whose stop cause is not input, the cause inputter 9 displays an alert on the display 4 in order to prompt an operator to input the stop cause of the stopped state. The alert continues to be shown until the operator inputs the stop cause.

FIG. 4 is a diagram illustrating an example of a display screen shown on the display 4. The display 4 shows information about stopped states that has occurred in the past in the equipment 10a and 10b monitored by the equipment operation state measurer 1. In the display screen shown in FIG. 4, a field “number” shows serial numbers (1 for newest) given to the stopped states that have occurred; a field “equipment” shows equipment that is in the stopped states; a field “time” shows the time at which the stopped states have occurred (and an end time of the stopped states in a case where the stopped states have been ended); a field “duration” shows duration of the stopped states; a field “portion” shows portions that have caused the stopped states of the equipment; a field “stop reason” shows stop causes that have generated the stopped states; a field “action” shows action taken to resolve the stopped states; and a field “stop type” shows classifications of the stop reasons for the stopped states.

Herein, a No. 1 stopped state is ongoing. The No. 1 stopped state is determined to have occurred at 12:00 by the operation state determiner 7. A stop cause is not input for the No. 1 stopped state. The cause inputter 9 issues an alert by showing a background of the line of the No. 1 stopped state with a design or color different from other lines on the display 4, so as to notify an operator of the occurrence of the stopped state. The alert with respect to the occurrence of the stopped state may also be issued in the form of displayed letters or sounds. An operator is asked to input information into each of the fields “portion”, “stop reason”, “action”, and “stop type” with respect to the No. 1 stopped state shown in the display 4. The operator investigates the portion at which the stopped state has occurred, a stop cause, and the like with respect to the equipment (press machine P1, in this example) in which the stopped state has occurred, and thereafter takes action on the equipment to resolve the stopped state. After confirming that the equipment has resumed to a normal operating state, the operator inputs information into the fields, “portion”, “stop reason”, “action”, and “stop type” for the No. 1 stopped state through the input device 5. For example, when the operator selects an “edit” button for the No. 1 stopped state, an input screen is shown on the display 4 with respect to each field for the No. 1 stopped state.

FIG. 5 is an example of an input screen. With respect to the fields, “equipment”, “time”, “portion”, “stop reason”, “action”, and “stop type”, the operator can select information to input from a dialog box or can input information by hand with a keyboard or the like. By pre-registering possible stop reasons and the like as available choices for the dialog box, it is possible to reduce operator's burden of inputting the information.

The cause inputter 9 accepts the operator's input with respect to each field showing a detailed operation state of the stopped state. The cause inputter 9 further stores the input information (stop causes, actions, and the like) in the memory 8 while associating the information with the stopped state (setting the information in each field of the stopped state).

In addition, it is also possible to divide a period that is detected as one stopped state into two states based on an input by an operator. For example, the former period may be set as a stopped state whose stop cause is a “breakdown”, and the latter period may be set as a stopped state whose stop cause is a “replacement of parts”.

When the operation state determiner 7 detects an end of a stopped state, the computing unit 6 computes duration of the stopped state, and obtains electric energy consumption in the stopped state by accumulating power consumption during the duration as a representative value of the power consumption for the stopped state. The computing unit 6 stores, in the memory 8, the duration and the electric energy consumption of the stopped state while associating them with the stopped state. Similarly, when the operation state determiner 7 detects an end of an operating state, the computing unit 6 computes duration of the operating state, and obtains electric energy consumption of the operating state by accumulating power consumption during the operating state. The computing unit 6 stores, in the memory 8, the duration and the electric energy consumption of the operating state while associating them with the operating state.

The calculator 2 of the equipment operation state measurer 1 outputs operation state data (operation state, electric energy consumption, stop cause, action, and the like) of the equipment 10a and 10b, stored in the memory 8, to an external data server 11 at a predetermined timing. The data server 11 also accepts data input from other equipment operation state measurers that measure operation states of other equipment. An administrator, an operator, or the like of a production line refers to the operation state data of each piece of equipment input into the data server 11 in order to acquire information regarding duration and electric energy consumption per stop cause with respect to each piece of equipment in the production line, in a form such as Table 1 shown below.

TABLE 1

| | | | Electric energy |
|---|---|---|---|
| Operation | | Duration | consumption |
| state | Cause | (h) | (kWh) |
| Operating state | Product 1 | 15.5 | 120 |
| Stopped state | Set-up | 3.5 | 5 |
| | Start-up and shut-down | 1.0 | 0.5 |
| | Breakdown | 1.0 | 0.25 |
| | Parts replacement | 3.0 | 6.25 |
| Power-off state | Breakdown | 2.0 | 0.03 |
| | Parts replacement | 3.5 | 0.05 |

Table 1 shows an example of duration and electric energy consumption in an operating state and each stopped state of equipment for a certain period. With respect to the stopped state, the duration and the electric energy consumption are obtained for each stop cause. The equipment operation state measurer 1 may perform processing to obtain the duration and the electric energy consumption for each stop cause before outputting the data to the data server 11. Accordingly, an administrator, an operator, or the like of a production line can analyze which equipment in the production line wastes a larger amount of time and electric energy, and thereby can take measures to reduce the waste of time and power consumption.

When the equipment operation state measurer 1 measures operation states of a plurality of equipment, only power meters corresponding to the number of target pieces of equipment need to be installed. Thus, even when operation states of a plurality of pieces of equipment are measured, the equipment operation state measurer 1 can be introduced at a lower cost.

In general, an operator monitors many pieces of equipment or works also on other duties, and thus a recollection of a stopped state in the past becomes unclear as time passes by. Inputting information into each field related to the stopped state becomes available to the operator immediately after the operation state determiner 7 determines an occurrence of a stopped state. In addition, since the cause inputter 9 issues an alert and prompts the operator for an immediate input, the operator can input information (stop cause, action, and the like) of the stopped state into the calculator 2 before forgetting the information. Thus, the equipment operation state measurer 1 can keep accurate records on operation states of the equipment 10a and 10b.

Further, an operator can input or edit the “time” field for a stop cause as needed. For example, when the time of occurrence of a stopped state detected by the operation state determiner 7 is different from an actual start time of the stopped state that is known to the operator, the operator can edit the information in the “time” field. Similarly, the operator can input or edit the end time of the stopped state (namely, the time when the equipment recovers).

Since the equipment operation state measurer 1 analyzes power consumption of equipment for predetermined duration in order to determine a start time and an end time of a stopped state, there is a delay in deciding the end time and the like. Thus, at the stage when an operator enters information into fields, the operation state determiner 7 has not necessarily finished deciding the end time of the stopped state. Therefore, with regard to the end time of a stopped state, an operator's input is given preference if there is any. If there is no input by an operator, a determination result by the operation state determiner 7 may be given preference.

In addition, there may be a case where an operator does not know a stop cause at the time when a stopped state occurs in equipment. In such a case, the operator can input the stop cause and the like only after the stopped state of the equipment has been resolved. Thus, an alert to prompt the operator to input the stop cause may be displayed after the operation state determiner 7 detects an end of the stopped state in the equipment. Thereby, it is possible to prevent the operator from forgetting to input the stop cause. Even in such a case, however, the cause inputter 9 may accept an input of the stop cause and the like by the operator at the time when the operation state determiner 7 detects the occurrence of the stopped state in the equipment.

Moreover, with regard to an operating state, the cause inputter 9 may accept from an operator an input of information on a processing object (detailed operation state information) in an operating state. For example, a field may be provided for an operating state to indicate a type of the processing object. In the example shown in Table 1, the information “product 1” is entered into the “cause” field to indicate the type of the object processed in the operating state.

The operator inputs the type of the object processed in the operating state into the equipment operation state measurer 1 via the input device 5. By doing so, when a user, such as an administrator or an operator of a production line, obtains the data shown in Table 1 from the data server 11, the user can recognize which processing object has been processed in the operating state. This information is useful in analyzing which processing object generates a larger amount of waste in time and power due to a malfunction, a set-up change, and the like in the equipment during processing.

Similarly, with regard to a power-off state, the cause inputter 9 may accept from an operator an input of information (power-off cause and the like) related to the power-off state. For example, with respect to a power-off state, the cause inputter 9 accepts an input of a cause that has turned off equipment. Examples of causes that turn off power (an operator turns off power) include a scheduled shut-down, a replacement of parts, maintenance, and the like. Thus, it is possible to acquire data such as that shown in Table 1, and to utilize the data to reduce waste of time and power consumption in the power-off state.

In the present embodiment, the power meters 3a and 3b are employed as an equipment measurer to measure power consumption of the equipment 10a and 10b in order to determine an operation state of the equipment 10a and 10b. Similarly, it is also possible to employ an ammeter to measure electric current in equipment in order to determine an operation state of the equipment 10a and 10b.

In addition, the computing unit 6 may obtain average power consumption over the duration of a stopped state as a representative value of the power consumption in the stopped state, and store the average power consumption in the memory 8. Moreover, instead of the duration of the stopped state and the like, the computing unit 6 may store, in the memory 8, data indicating a start time and an end time of the stopped state.

Next, a flow of processes performed by the equipment operation state measurer 1 to record an operation state of equipment is described with reference to FIG. 6. FIG. 6 is a flow chart illustrating an example of a process flow performed in the equipment operation state measurer 1 to record the operation state of the equipment.

The power data acquirer 12 acquires power consumption data of the equipment from an external device, and stores (records) the data in the memory 8.

The operation state determiner 7 acquires, from the memory 8, time series power consumption data from a time of a previous acquisition of power consumption data to present time at predetermined intervals (S1). The operation state determiner 7 determines an operation state of the equipment based on the acquired power consumption data, and then determines whether or not there has been any change in the operation state (change from an operating state to a stopped state, change from a stopped state to an operating state, change in a stop cause of a stopped state, or the like) (S2). When there is no change in the operation state (“No” in S2), the process goes back to step S1.

When there is a change in the operation state (“Yes” in S2), the computing unit 6 obtains duration of a recently terminated operation state and electric energy consumption that is accumulated power consumption for the duration of the operation state (S3). When the recently terminated operation state is a stopped state and a stop cause is not set for the stopped state (“No” in S4), or when a recently started operation state is a stopped state (“No” in S4), the cause inputter 9 displays an alert on the display 4 to prompt an operator for an input of a stop cause of the stopped state (S5). After the operator inputs the stop cause of the stopped state via the input device 5, the cause inputter 9 sets the stop cause of the stopped state based on the input (S6).

When a stop cause is set for the recently terminated stopped state and also the recently started operation state is not a stopped state (“Yes” in S4), and when a stop cause is set for the stopped state by the operator (S6), total duration of the stopped state for each stop cause and total electric energy consumption for the duration of the stopped state are obtained while taking into account data for stopped states over a past period (the last one month, for example) (S7). The process is completed here.

### Second Embodiment

In the configuration of the first embodiment, a stop cause and the like is determined for each stopped state based on an input of the stop cause and the like by an operator to the cause inputter. However, the equipment operation state measurer may determine a stop cause and the like based on information input from an external sensor. In the present embodiment, descriptions are provided for a configuration that employs a temperature sensor as the above sensor to acquire temperature information (state information) of an object piece of equipment and to determine a stop cause. As a matter of convenience in description, only points different from the first embodiment are described hereinafter.

FIG. 7 is a block diagram showing a configuration of an equipment operation state measurer 16 according to the present embodiment. The calculator 2 of the equipment operation state measurer 16 includes a temperature data acquirer (state information acquirer) 13 and a cause determiner (detailed operation state determiner) 14. A temperature sensor 15 measures the temperature of the equipment 10a.

The temperature data acquirer 13 acquires temperature information of the equipment 10a as state information of the equipment 10a from the temperature sensor 15. The cause determiner 14 determines a stop cause of the equipment 10a based on the acquired temperature information of the equipment 10a. A specific example of the determination is described hereinafter.

FIG. 8 is a chart illustrating an example of a graph that is a time series plot of power consumption of the equipment 10a measured by the power meter 3a and temperature of the equipment 10a measured by the temperature sensor 15. A scale on the left side of the graph indicates the power consumption, and a scale on the right side indicates the temperature. The temperature is indicated in a heavy line in the graph.

The equipment 10a consumes a certain amount of power and generates heat in an operating state and a stopped state. Thus, temperature measured by the temperature sensor 15 is substantially constant in the operating state and the stopped state. When the equipment 10a is turned off, the temperature of the equipment 10a drops and becomes close to room temperature. Herein, a temperature threshold value V5 is set higher than the room temperature and lower than the constant temperature in the operating state or the stopped state. A period between a time t_{8 and a time t}₁₀ is determined to be a stopped state based on the power consumption as described in the first embodiment. When the temperature of the equipment 10a at the time t₈, which is a start time of the stopped state, is lower than the temperature threshold value V5, the cause determiner 14 determines that the stop cause of the stopped state is a “start-up (start-up of the equipment)”.

The cause determiner 14 inputs the stop cause of the stopped state into the cause inputter 9. The cause inputter 9 sets the input stop cause as a stop cause of the stopped state, and stores the stop cause in the memory 8 while associating the stop cause with the stopped state.

The cause inputter 9 may accept an input from an operator separately from the input from the cause determiner 14. In other words, a stop cause determined by the cause determiner 14 may be displayed on a display so that the operator can edit the stop cause as needed.

### Third Embodiment

In the present embodiment, descriptions are provided for a configuration that acquires vibration information (state information) of an object piece of equipment using a vibration sensor and determines a stop cause. As a matter of convenience in description, only points different from the first embodiment are described hereinafter.

FIG. 9 is a block diagram illustrating a configuration of an equipment operation state measurer 17 according to the present embodiment. The calculator 2 of the equipment operation state measurer 17 includes a vibration data acquirer (state information acquirer) 18 and a cause determiner (detailed operation state determiner) 19. A vibration sensor 20 measures vibration of the equipment 10a.

The vibration data acquirer 18 acquires, from the vibration sensor 20, vibration information of the equipment 10a as state information of the equipment 10a. The cause determiner 19 determines a stop cause of the equipment 10a based on the acquired vibration information of the equipment 10a. A specific example of the determination is described hereinafter.

FIG. 10 is a chart illustrating an example of a graph that is a time series plot of power consumption of the equipment 10a measured by the power meter 3a and vibration energy obtained from the vibration of the equipment 10a measured by the vibration sensor 20. A scale on the left side of the graph indicates the power consumption, and a scale on the right side indicates the vibration energy. The vibration energy is indicated in a heavy line in the graph.

The cause determiner 19 obtains vibration energy from the acquired vibration information. During a period at or before a time t₁₁ and a period at or after a time t_{15, the equipment 10}a is in an operating state. In the operating state, the equipment 10a vigorously vibrates, and the detected vibration energy thereof is large. In addition, during a period between the time t₁₃ and the time t₁₅, for example, although the equipment 10a is in a stopped state, there is generally a stand-by vibration, and a certain level of vibration energy is detected. However, when the equipment 10a completely stops its physical activities due to a breakdown occurring while the equipment 10a is in an operating state, as shown at the time t₁₁ in FIG. 10, the vibration energy suddenly becomes close to 0. Further, during a period between the time t₁₁ and a time t₁₂, although the equipment 10a is in a stopped state while its power is on, the detected vibration energy is close to 0. Herein, a vibration energy threshold value V6 is set lower than the vibration energy value of the operating state. A vibration energy threshold value V7 is set higher than 0 and lower than the lowest vibration energy value of a normal stopped state. When there is a point at which the vibration energy rapidly changes from a value higher than the vibration energy threshold value V6 to a value lower than the vibration energy threshold value V7 before and after the time t₁₁, which is the start time of the stopped state, the cause determiner 19 determines that the stop cause of the stopped state is a “breakdown”.

The cause determiner 19 inputs the stop cause of the stopped state to the cause inputter 9. The cause inputter 9 stores the input stop cause in the memory 8 while associating the input stop cause with the stopped state.

### Fourth Embodiment

In the present embodiment, descriptions are provided for a configuration that acquires image information (state information) of the processing object of an object piece of equipment using an image sensor and determines a stop cause. As a matter of convenience in description, only points different from the first embodiment are described hereinafter.

FIG. 11 is a block diagram illustrating a configuration of an equipment operation state measurer 21 according to the present embodiment. The calculator 2 of the equipment operation state measurer 21 includes an image data acquirer (state information acquirer) 22 and a cause determiner (detailed operation state determiner) 23. An image sensor 24 captures an image of a processing object of the equipment 10a.

The image data acquirer 22 acquires, from the image sensor 24, image information of the processing object carried into the equipment 10a as state information of the equipment 10a. The cause determiner 23 determines a stop cause of the equipment 10a based on the acquired image information of the processing object. A specific example of the determination is described hereinafter.

FIG. 12 is a chart illustrating an example of a graph that is a time series plot of power consumption of the equipment 10a measured by the power meter 3a. In the example shown in FIG. 12, a period at or before a time t₁₆ is an operating state. A period between the time t₁₆ and a time t₁₇ is a stopped state. A period between the time t₁₇ and a time t₁₈ is a power-off state. A period between the time t₁₈ and a time t₂₀ is a stopped state. A period at or after the time t₂₀ is an operating state.

The cause determiner 23 determines a type of processing object being carried into the equipment 10a based on the acquired image information of the processing object. In this example, a type of processing object carried into the equipment 10a during an operating state at or before the time t₁₆ is different from a type of processing object carried into the equipment 10a during an operating state at or after the time t₂₀. In this case, it is considered that a set-up change due to a change of processing objects is performed during the period between the time t₁₆ and the time t₂₀. The cause determiner 23 compares the type of the processing object in the former operating state with the type in the latter operating state after the equipment 10a resumes the operating state at the time t₂₀. When the type of the processing object in the former operating state is different from the type of the processing object in the latter operating state, the stop cause of the stopped state between the two operating states is determined to be “set-up”. Alternatively, a power-off cause of a power-off state between the two operating states may be determined to be “set-up”.

The cause determiner 23 inputs, into the cause inputter 9, the stop cause of the stopped state or the power-off cause of the power-off state. The cause inputter 9 stores the input stop cause in the memory 8 while associating the input stop cause with the operating state. The cause determiner 23 determines a type of a product based on the type of the processing object, and inputs into the cause inputter 9 the information of the product type as the detailed operation state information of the operating state. The cause inputter 9 stores the input product type information in the memory 8 while associating the input product type information with the operating state.

### Fifth Embodiment

In the present embodiment, descriptions are provided for a configuration that estimates a stop cause of a stopped state, using power consumption data that is associated with a time and stored in the memory 8, and past operation state data (operation state, power consumption, stop cause, action, and the like) stored in the data server 11. As a matter of convenience in description, only points different from the first embodiment are described hereinafter.

FIG. 13 is a block diagram illustrating a configuration of an equipment operation state measurer 30 according to the present embodiment. The calculator 2 of the equipment operation state measurer 30 includes a cause estimator (detailed operation state estimator) 25 and a feature amount calculator 33.

The feature amount calculator 33 analyzes power consumption data acquired by the power data acquirer 12, power consumption data stored in the memory 8, or power consumption data stored in the data server 11; and calculates a feature amount of the power consumption data.

The cause estimator 25 calculates a degree of similarity between a feature amount of power consumption data of a predetermined period before a start of a stopped state whose cause has not been input (whose cause has not been determined) and a feature amount of power consumption data of a stopped state whose cause is known and stored in the memory 8 and the data server 11, the power consumption data being from a predetermined period before the start of the stopped state. Then, a cause of a stopped state having a feature amount whose degree of similarity is highest (a feature amount is similar) is estimated as a cause of the stopped state whose cause has not been input (no stop cause has been determined). The cause estimator 25 outputs the estimated cause into the cause inputter 9. A specific example of estimating a stop cause is described hereinafter.

For example, when a heating cylinder is contaminated with a foreign substance, an abnormal stop occurs in equipment after several days. During the several days from the contamination of the foreign substance to the abnormal stop, the state of the equipment is different from a normal operating state, and thus a variation or a delay occurs in tact time.

Thus, in order to determine whether or not the reason of the abnormal stop is due to the contamination of the foreign substance in the hating cylinder, a frequency analysis, such as a Fourier transform, is performed on power consumption data from a predetermined period immediately before the abnormal stop and power consumption data of a normal operating state. Results of the frequency analysis are shown in FIGS. 14 (a) and (b). FIG. 14(a) is a graph showing a result of the frequency analysis on the power consumption data of the predetermined period immediately before the abnormal stop. FIG. 14(b) is a graph showing a result of the frequency analysis on the power consumption data of a normal operating state. In both FIGS. 14(a) and (b), a horizontal axis indicates frequency and a vertical axis indicates amplitude.

Since a variation or a delay occurs in tact time during the several days before the abnormal stop, as shown in FIGS. 14(a) and (b), distribution of frequency components in the analysis result for the period immediately before the abnormal stop is different from that of the normal operating state. Specifically, in the analysis result for the period immediately before the abnormal stop, amplitude of the peak frequency is smaller and bandwidth of the peak frequency is wider than those of the normal operating state.

The feature amount calculator 33 performs a frequency analysis on power consumption data of the predetermined period immediately before the abnormal stop, and calculates amplitude and bandwidth of a peak frequency. The cause estimator 25 compares the amplitude and bandwidth of the peak frequency calculated by the feature amount calculator 33 with the amplitude and bandwidth of the peak frequency immediately before the abnormal stop and also of the normal operating state. Accordingly, it is possible to estimate whether or not the stop cause of the stopped state is due to the contamination of the heating cylinder with the foreign substance.

Only one cause of a stopped state is described here. However, there is a case where a plurality of stop causes are known for a stopped state, and feature amounts to identify each cause are stored in the memory 8 or the data server 11 while associating a stopped state with each of the causes. In such a case, the cause estimator 25 may calculate a degree of similarity between a feature amount that is a result of an analysis on the power consumption data of the predetermined period immediately before the stopped state and the feature amount stored in the memory 8 or the data server 11, in order to estimate a cause that is associated with the index having the highest degree of similarity as the cause of the stopped state.

Examples of methods used by the cause estimator 25 to calculate a degree of similarity include pattern matching and the like, such as SMV (Support Vector Machine), NN (Nearest Neighbors), clustering, or the like. However, the method is not limited to pattern matching, and any method may be used as long as the method can calculate the degree of similarity (degree of approximation).

Further, a method used by the feature amount calculator 33 to calculate a feature amount is not limited to a frequency analysis, and any method may be used as long as the method can calculate a feature amount that stores the cause of an operation state. In addition, a feature amount is not limited to amplitude or bandwidth of a peak frequency, and any index may be used as long as the index can determine a cause of an operation state.

Furthermore, in the present embodiment, a memory including at least one of the memory 8 and the data server 11 is referred to as a first memory. The first memory stores a cause of an operation state, while associating the cause with a feature amount of power consumption data acquired by the power data acquirer 12 from the period immediately before the operation state.

### Sixth Embodiment

In this embodiment, descriptions are provided for a configuration that estimates a cause of a stopped state based on a sequential relationship of operation states, by referring to operation state data determined by the operation state determiner 7 and operation state data history stored in the data server 11. As a matter of convenience in description, only points different from the first embodiment are described hereinafter.

FIG. 15 is a block diagram illustrating a configuration of an equipment operation state measurer 31 according to the present embodiment. The calculator 2 of the equipment operation state measurer 31 includes a cause estimator (detailed operation state estimator) 26. In the present embodiment, either one of the memory 8 and the data server 11 stores a known cause of a stopped state and a sequence of a plurality of operation states including the stopped state that is associated with the cause of the stopped state.

The cause estimator 26 identifies a sequence of the operation states, stored in either the memory 8 or the data server 11, that matches a sequence (state transition sequence) of a plurality of operation states including the stopped state determined by the operation state determiner 7. Then, the cause estimator 26 estimates that the cause of the stopped state determined by the operation state determiner 7 is the same as the cause of the stopped state associated with the identified sequence of the operation states stored in either the memory 8 or the data server 11. The cause estimator 26 not only estimates a cause of a stopped state determined by the operation state determiner 7, but may also similarly estimate a cause of a stopped state that is stored in either the memory 8 or the data server 11 and whose cause has not been determined. A specific example of estimating a stop cause is described hereinafter.

For example, in a case where the equipment 10a is a molding machine and the molding machine is started up from a power-off state, the molding machine first enters a heating state and then enters an operating state after a stopped state. In other words, the sequence of operation states is as follows: a power-off state, a heating state, a stopped state, and then an operating state. Herein, a heating state is a state where equipment is heated up to an operable temperature by, for example, a heater. In this state, power consumption is more than or equal to that in an operating state. Since more than or equal to a certain constant amount of power is consumed, the operation state determiner 7 determines the heating state as an operating state. In such a case, with a temperature data acquirer such as the temperature sensor described in the second embodiment being provided, by measuring the temperature of the molding machine, the operation state determiner 7 can further specify whether the state determined by itself is actually an operating state or a heating state.

In other words, when a sequence of a plurality of the operation states, including a stopped state determined (specified) by the operation state determiner 7, is a power-off state, a heating state, a stopped state, and then an operating state, the cause estimator 26 extracts a sequence of operation states, stored in the memory 8 or the data server 11, that is identical with the sequence of the operation states. The cause estimator 26 uses a “start-up”, which is a cause of a stopped state that is associated with the extracted sequence of the operation states, and estimates the stop cause of the stopped state determined by the operation state determiner 7. Thereafter, the cause estimator 26 outputs the estimated stop cause “start-up” of the stopped state to the cause inputter 9.

In the present embodiment, a memory that includes at least either one of the memory 8 and the data server 11 is referred to as a second memory. The second memory stores a cause of an operation state while associating the cause with a state transition sequence of a plurality of operation states including the operation state.

### Seventh Embodiment

In the present embodiment, descriptions are provided for a configuration that acquires information on a state of an object piece of equipment using various sensors and determines a stop cause. As a matter of convenience in description, only points different from the first embodiment are described hereinafter.

FIG. 16 is a block diagram illustrating a configuration of an equipment operation state measurer 32 according to the present embodiment. The calculator 2 of the equipment operation state measurer 32 includes a state information acquirer (state information acquirer) 28 and a cause determiner (detailed operation state determiner) 27. Various sensors 29 measure or detect a state of the equipment 10a. The various sensors 29 are described in detail later.

The state information acquirer 28 acquires from the various sensors 29 information regarding a state of the equipment 10a measured or detected by the various sensors 29 as state information. The cause determiner 27 determines a stop cause of the equipment 10a based on the acquired information regarding the state of the equipment 10a. A specific example of the determination is described hereinafter.

First, with reference to FIG. 17, a determination example is described for a case where one of the various sensors 29 is a weight sensor that measures the weight of products flowing on a line of the equipment 10a. FIG. 17 is a chart illustrating an example of a graph that is a time series plot of power consumption of the equipment 10a measured by the power meter 3a and weight of the products flowing on the line of the equipment 10a measured by the weight sensor. A scale on the left side of the graph indicates the power consumption, and a scale on the right side indicates the weight of products (units in grams). The weight of products is shown in a thick line in the graph.

As shown in FIG. 17, the equipment 10a is in an operating state during a period at or before a time t₂₁ and a period at or after a time t₂₅. Since products are constantly flowing on the line, values measured by the weight sensor are a certain constant value. Further, although the equipment 10a is in a stopped state during a period, for example, between a time t₂₃ and the time t₂₅, this is a test-operating state transitioning from a power-off state to an operating state. Since materials or products may flow on the line during the test-operating state, the weight sensor detects a certain amount of weight. However, in a case where a breakdown occurs while the equipment 10a is in an operating state and physical activities thereof are completely terminated, a value of the weight sensor rapidly drops close to 0, as shown at the time t₂₁ of FIG. 17. In addition, during a period between the time t₂₁ and a time t₂₂, even when the equipment 10a is in a stopped state where the power thereof is turned on, a detected weight value is close to 0. In periods before and after a stopped state determined by the operation state determiner 7, when a weight value measured by the weight sensor rapidly changes from a constant value to 0 during a predetermined period, the cause determiner 27 determines that the stop cause of the stopped state is a “breakdown”.

Next, with reference to FIG. 18, a determination example is described for a case where one of the various sensors 29 is a material input sensor that measures an amount of material input, which is a weight (volume) of materials input into the equipment 10a such as a molding machine or the like. FIG. 18 is a chart illustrating an example of a graph that is a time series plot of power consumption of the equipment 10a measured by the power meter 3a and a weight (volume) of materials input into the equipment 10a measured by the material input sensor. A scale on the left side of the graph indicates the power consumption, and a scale on the right side indicates the amount of material input. The material input amount is shown in a thick line in the graph.

As shown in FIG. 18, the equipment 10a is in an operating state during a period at or before a time t₂₆ and a period at or after a time t₃₀. In this state, products are steadily manufactured, and a constant amount of product materials is continuously input. Thus, a value measured by a material input sensor is a certain constant weight value in the operating state. Further, the equipment 10a is in a stopped state during a period, for example, between a time t₂₈ and the time t₃₀. However, this state is a test-operating state transitioning from a power-off state to an operating state, and materials are input little by little. Thus, when the material input sensor intermittently measures a predetermined value that is smaller than an amount of material input of an operating state in the period (between the time t₂₈ and the time t₃₀) determined to be a stopped state by the operation state determiner 7, and further measures value for an amount of material input of the operating state in a period at or after the time t₃₀, the cause determiner 27 determines that the stop cause of the stopped state is “set-up”. In other words, by referring to a value measured by the material input sensor, the cause determiner 27 can determine that the stop cause of the stopped state after a start of a test-operating state and before an operating state is “set-up”.

Next, with reference to FIG. 19, a determination example is described for a case where one of the various sensors 29 is an image sensor that captures an image of a rotating warning light (not shown) provided to the equipment 10a. The above rotating warning light irradiates lights in blue, orange, red, and the like in order to inform an equipment administrator of a status of the equipment (operating, replacement, and breakdown). Herein, the rotating warning light in blue indicates an operating state. The rotating warning light in orange indicates a state of a replacement. The rotating warning light in red indicates a state of a breakdown. When the rotating warning light is not emitting light (colorless), it indicates a power-off state. FIG. 19 is a chart illustrating an example of a graph that is a time series plot of power consumption of the equipment 10a measured by the power meter 3a and a color of a rotating warning light captured by the image sensor. A scale on the left side of the graph indicates the power consumption, and a scale on the right side indicates the color of the rotating warning light. The color of the rotating warning light is shown in a thick line in the graph.

As shown in FIG. 19, the color of the rotating warning light is red during a period between a time t₃₁ and a time t₃₂, colorless during a period between the time t₃₂ and a time t₃₃, and orange during a period between the time t₃₃ and a time t₃₅. Thus, the cause determiner 27 determines that a stop cause of the stopped state during the period between the time t₃₁ and the time t₃₂ is a “breakdown”. The cause determiner 27 determines that a power-off cause of the power-off state during the period between the time t₃₂ and the time t₃₃ is a “power-off”. The cause determiner 27 further determines that a stop cause of the stopped state during the period between the time t₃₃ and the time t₃₅ is a “replacement”.

Next, with reference to FIG. 20, a determination example is described for a case where one of the various sensors 29 is a motor revolution sensor that measures the number of revolutions of a motor provided to the equipment 10a (press machine and the like). FIG. 20 is a chart illustrating an example of a graph that is a time series plot of power consumption of the equipment 10a measured by the power meter 3a and the number of motor revolutions measured by the motor revolution sensor. A scale on the left side of the graph indicates the power consumption, and a scale on the right side indicates the number of the motor revolutions. The number of motor revolutions is shown in a thick line in the graph.

As shown in FIG. 20, during a period at or before a time t₃₆ and a period at or after a time t₄₀, the equipment 10a is in an operating state and steadily manufacturing products. In this state, the motor of the equipment 10a rotates at a constant number of revolutions. Thus, values measured by the motor revolution sensor have a certain constant number of revolutions in an operating state. In addition, the equipment 10a is in a stopped state during a period, for example, between a time t₃₈ and the time t₄₀. However, this state is a test-operating state transitioning from a power-off state to an operating state, and has intermittent increases in the number of revolutions of the motor. Thus, when the motor revolution sensor intermittently measures revolution number having a predetermined value but smaller than that of an operating state in the period (between the time t₃₈ and the time t₄₀) determined as a stopped state by the operation state determiner 7, and also measures in the period at or after the time t₄₀ the revolution number of the motor of an operating state, the cause determiner 27 determines that a stop cause of the stopped state is “set-up”. In other words, by referring to the value measured by the motor revolution sensor, the cause determiner 27 can determine that a stop cause of the stopped state after the start of the test-operating state and before the operating state is “set-up”.

Next, with reference to FIG. 21, a determination example is described for a case where the equipment 10a includes an inverter, and one of the various sensors 29 is a frequency sensor that measures a frequency of the inverter. FIG. 21 is a chart illustrating an example of a graph that is a time series plot of power consumption of the equipment 10a measured by the power meter 3a and the inverter frequency measured by the frequency sensor. A scale on the left side of the graph indicates the power consumption, and a scale on the right side indicates the frequency. The frequency is shown in a thick line in the graph.

As shown in FIG. 21, during a period at or before a time t₄₁ and a period at or after a time t₄₅, the equipment 10a is in an operating state and steadily manufacturing products. In this state, the frequency of the inverter is substantially constant. Thus, values measured by the frequency sensor have substantially constant frequency values in an operating state. In addition, the equipment 10a is in a stopped state during a period, for example, between a time t₄₃ and the time t₄₅. However, this state is a test-operating state transitioning from a power-off state to an operating state. In the test-operating state, the frequency of the inverter gradually increases up to the frequency value of the operating state. Thus, in the period (between the time t₄₃ and the time t₄₅) determined as a stopped state by the operation state determiner 7, when the frequency measured by the frequency sensor gradually increases up to the inverter frequency of the operating state (until the frequency becomes a substantially constant value), the cause determiner 27 determines the stop cause of the stopped state is a “shut-down”.

Next, with reference to FIG. 22, a determination example is described for a case where one of the various sensors 29 is a compressed air flow sensor that measures a flow rate of compressed air, when the equipment 10a uses the compressed air at a time of manufacturing products. FIG. 22 is a chart illustrating an example of a graph that is a time series plot of power consumption of the equipment 10a measured by the power meter 3a and the flow rate of the compressed air measured by the compressed air flow sensor. A scale on the left side of the graph indicates the power consumption, and a scale on the right side indicates the flow rate of the compressed air. The flow rate of the compressed air is shown in a thick line in the graph.

As shown in FIG. 22, during a period at or before a time t₄₆ and a period at or after a time t₅₀, the equipment 10a is in an operating state and steadily manufacturing products. In this state, the compressed air used by the equipment 10a flows at a constant rate. Thus, values measured by the compressed air flow sensor have a certain constant value in an operating state. In addition, the equipment 10a is in a stopped state during a period, for example, between a time t₄₈ and the time t₅₀. However, this state is a test-operating state transitioning from a power-off state to an operating state. In the test-operating state, the flow rate of the compressed air is smaller than that of the operating state, but also intermittently increases. Thus, when the compressed air flow sensor intermittently measures a flow rate having a predetermined value but smaller than that of the operating state in the period (between the time t₄₈ and the time t₅₀) determined as a stopped state by the operation state determiner 7 after it has determined a power-off state, and also when the compressed air flow sensor measures the flow rate (constant flow rate) of the compressed air of the operating state in a period at or after the time t₅₀, the cause determiner 27 determines that the stop cause of the stopped state is a “start-up”.

Next, with reference to FIG. 23, a determination example is described for a case where one of the various sensors 29 is a cooling water flow sensor that measures a flow rate of cooling water used by the equipment 10a. FIG. 23 is a chart illustrating an example of a graph that is a time series plot of power consumption of the equipment 10a measured by the power meter 3a and a flow rate of the cooling water measured by the cooling water flow sensor. A scale on the left side of the graph indicates the power consumption, and a scale on the right side indicates the flow rate of the cooling water. The cooling water is shown in a thick line in the graph.

As shown in FIG. 23, during a period at or before a time t₅₁ and a period at or after a time t₅₅, the equipment 10a is in an operating state and steadily manufacturing products. In this sate, the flow rate of the cooling water is substantially constant. Thus, values measured by the cooling water flow sensor have a substantially constant value in an operating state. In addition, the equipment 10a is in a stopped state during a period, for example, between a time t₅₃ and the time t₅₅. However, this state is a test-operating state transitioning from a power-off state to an operating state. In the test-operating state, the flow rate of the cooling water gradually increases up to the flow rate value of the cooling water of the operating state. Thus, in the period (between the time t₅₃ and the time t₅₅) determined as a stopped state by the operation state determiner 7, when the flow rate of the cooling water detected by the cooling water flow sensor gradually increases up to the flow rate of the cooling water of the operating state (until flow rate value becomes substantially constant), the cause determiner 27 determines that the stop cause of the stopped state is a “shut-down”.

The present embodiment describes examples of the cases where the various sensors 29 are a weight sensor, a material input sensor, an image sensor, a motor revolution sensor, a frequency sensor, a compressed air flow sensor, and a cooling water flow sensor. However, the various sensors 29 are not limited to these sensors. The various sensors 29 may be any sensor as long as it can acquire state information that changes in accordance with an operation state of the equipment 10a. In addition, the various sensors 29 may acquire a plurality of state information.

Lastly, each component of the calculator 2 of the equipment operation state measurer 1, especially the computing unit 6, the operation state determiner 7, the cause inputter 9, and the power data acquirer 12 may be configured with a hardware logic, or a software employed along with a CPU (central processing unit) as described in the following.

Specifically, the equipment operation state measurer 1 includes a CPU that executes instructions of a control program that executes each function; a ROM (read only memory) that stores the program; a RAM (Random Access Memory), in which the program is executed; a storage (recording medium), such as a memory, that stores the program and various data; and the like. The equipment operation state measurer 1 is provided with a recording medium that stores computer-readable program codes (an executable program, an intermediate code program, and a source program) of the control program of the equipment operation state measurer 1, the control program being software to execute the above functions. Further, a computer (alternatively, CPU or MPU (microprocessor unit)) reads out and executes the program codes stored in the recording medium. Thereby, the object of the present invention can be also achieved.

Examples of the recording medium include, for example, a tape, such as a magnetic tape, a cassette tape, or the like; a disc including an magnetic disk such as a floppy (a registered trademark) disc, a hard disc or the like, and an optical disc such as a CD-ROM (compact disc read-only memory), MO (magneto-optical), MD (Mini Disc), DVD (digital versatile disc), CD-R (CD recordable) or the like; a card, such as an IC card (including a memory card), an optical card, or the like; or a semiconductor memory, such as a mask ROM, EPROM (erasable programmable read-only memory), EEPROM (electrically erasable and programmable read-only memory), a flash ROM, or the like.

The equipment operation state measurer 1 may be configured to be connectable to a communication network, thorough which the program codes may be provided. The communication network is not limited to a specific type, and may be configured with, for example, the interne, an intranet, an extranet, LAN (local area network), ISDN (integrated services digital network), VAN (value-added network), CATV (community antenna television) communication network, a virtual private network, a telephone network, a mobile communication network, a satellite communication network, or the like. A transmission medium that configures the communication network is not limited to a specific type, and may be configured with, for example, a wired medium, such as an IEEE (institute of electrical and electronic engineers) 1394, a USB, a power-line carrier, a cable TV line, a telephone line, an ADSL (a synchronous digital subscriber loop) line or the like; and a wireless medium, such as an infrared ray including an IrDA (infrared data association) and a remote controller, a Bluetooth (a registered trademark), an IEEE 802.11 wireless LAN, an HDR (high data rate), a mobile communication network, a satellite connection network, a digital terrestrial communication, or the like. The present invention can be also executed by an electronic transmission of the program code, such as a computer data signal embedded in the transmitted wave.

It is noted that the foregoing examples are in no way to be construed as limiting of the present invention. Changes may be made, within the purview of the appended claims, as presently stated, without departing from the spirit of the present invention. Embodiments obtained by combining the technical features disclosed in different embodiments are also included in the technical scope of the present invention.

### INDUSTRIAL APPLICABILITY

The present invention is applicable for an equipment operation state measurer that measures duration or a physical quantity for each operation state of equipment that executes various steps in a production line.

### DESCRIPTION OF REFERENCE NUMERALS

1, 16, 17, 21, 30, 31, 32 Equipment operation state measurer

2 Calculator

3a, 3b Power meter (Equipment measurer)

4 Display

5 Input device

6 Computing unit (Computer)

7 Operation state determiner

8 Memory (First memory and Second memory)

9 Cause inputter (Information input)

10a, 10b Equipment

11 Data server (First memory and Second memory)

12 Power data acquirer (Physical quantity acquirer)

13 Temperature data acquirer (State information acquirer)

14, 19, 23, 27 Cause determiner (Detailed operation state determiner)

15 Temperature sensor

18 Vibration data acquirer (State information acquirer)

20 Vibration sensor

22 Image data acquirer (State information acquirer)

24 Image sensor

25, 26 Cause estimator (Detailed operation state estimator)

28 State information acquirer

29 Various sensors

33 Feature amount calculator

1. An equipment operation state measurer, comprising:
a physical quantity acquirer that acquires a physical quantity that changes according to an operation state of equipment;
an operation state determiner that determines an operation state of the equipment based on the physical quantity; and
an information inputter that accepts an input of information corresponding to a detailed operation state of the operation state determined by the operation state determiner, and sets the detailed operation state of the operation state based on the accepted input.

2. The equipment operation state measurer according to claim 1, wherein the operation state determiner determines whether an operation state of the equipment is an operating state or a stopped state based on the physical quantity.

3. The equipment operation state measurer according to claim 1, wherein the physical quantity is electric power or electric current.

4. The equipment operation state measurer according to claim 1, comprising:
a state information acquirer that acquires state information that changes according to an operation state of the equipment; and
a detailed operation state determiner that determines, based on the state information and an operation state determined by the operation state determiner, a detailed operation state of the operation state and inputs information corresponding to the detailed operation state of the operation state into the information input.

5. The equipment operation state measurer according to claim 1, comprising:
a computer that obtains, with respect to each detailed operation state, a period during which an operation state corresponding to the detailed operation state continues; and obtains a representative value of the physical quantity from the period during which the operation state continues.

6. The equipment operation state measurer according to claim 1, wherein, when there is an operation state whose detailed operation state is not set, the information inputter issues an alert to prompt for an input of information relating to the detailed operation state of the operation state.

7. The equipment operation state measurer according to claim 1, wherein the operation state determiner that determines whether an operation state of the equipment is an operating state, a stopped state, or a power-off state based on the physical quantity.

8. The equipment operation state measurer according to claim 2, wherein the information inputter accepts an input of a stop cause as information relating to a detailed operation state of a stopped state determined by the operation state determiner, and sets the stop cause of the stopped state based on the accepted input.

9. The equipment operation state measurer according to claim 2, wherein the information inputter accepts an input of information relating to a processing object as information regarding a detailed operation state of an operating state determined by the operation state determiner, and sets the information relating to the processing object of the operating state based on the accepted input.

10. The equipment operation state measurer according to claim 7, wherein the information inputter accepts an input of a power-off cause as information relating to a detailed operation state of a power-off state determined by the operation state determiner, and sets the power-off cause of the power-off state based on the accepted input.

11. The equipment operation state measurer according to claim 4, wherein the state information acquirer acquires temperature information of the equipment as the state information.

12. The equipment operation state measurer according to claim 4, wherein the state information acquirer acquires vibration information of the equipment as the state information.

13. The equipment operation state measurer according to claim 4, wherein the state information acquirer acquires image information of a processing object of the equipment as the state information.

14. The equipment operation state measurer according to claim 1, comprising:
a feature amount calculator that analyzes the physical quantity acquired by the physical quantity acquirer, and calculates a feature amount of the physical quantity; and
a detailed operation state estimator that
refers to a first memory that stores a detailed operation state of an operation state and the feature amount of the physical quantity acquired by the physical quantity acquirer from a predetermined period before a start of the operation state, the detailed operation state of the operation state and the feature amount of the physical quantity being associated with each other,
uses a detailed operation state that is associated with the feature amount stored in the first memory and being most similar to the feature amount of the physical quantity acquired by the physical quantity acquirer from the predetermined period before a start of an operation state determined by the operation state determiner, and estimates the detailed operation state as a detailed operation state of the operation state determined by the operation state determiner; and
inputs information relating to the estimated detailed operation state into the information inputter.

15. The equipment operation state measurer according to claim 1, comprising:
a detailed operation state estimator that
refers to a second memory that stores a detailed operation state of an operation state and a state transition sequence of a plurality of operation states including the operation state, the detailed operation state of the operation state and the state transition sequence being associated with each other;
extracts, from the second memory, a state transition sequence of operation states that matches a state transition sequence of a plurality of operation states including an operation state determined by the operation state determiner;
estimates a detailed operation state that is associated with the extracted state transition sequence of the operation states as a detailed operation state of the operation state determined by the operation state determiner; and
inputs information relating to the estimated detailed operation state into the information inputter.

16. An equipment operation state measurement method comprising:
acquiring a physical quantity that changes according to an operation state of equipment;
determining an operation state of the equipment based on the physical quantity; and
accepting an input of information relating to a detailed operation state of the determined operation state, and setting the detailed operation state of the operation state based on the accepted input.

17. A non-transitory computer readable storage medium having computer instructions stored thereon comprising a program, the program causing a computer to perform:
a physical quantity acquisition that acquires a physical quantity that changes according to an operation state of equipment;
an operation state determination that determines an operation state of the equipment based on the physical quantity; and
an information inputting that accepts an input of information regarding a detailed operation state of the operation state determined by the operation state determining step, and sets the detailed operation state of the operation state based on the accepted input.

18. The equipment operation state measurer according to claim 2, wherein the physical quantity is electric power or electric current.

19. The equipment operation state measurer according to claim 2, comprising:
a state information acquirer that acquires state information that changes according to an operation state of the equipment; and
a detailed operation state determiner that determines, based on the state information and an operation state determined by the operation state determiner, a detailed operation state of the operation state and inputs information corresponding to the detailed operation state of the operation state into the information input.

20. The equipment operation state measurer according to claim 2, comprising:
a computer that obtains, with respect to each detailed operation state, a period during which an operation state corresponding to the detailed operation state continues; and obtains a representative value of the physical quantity from the period during which the operation state continues.
